(19) United States
(12) Patent Application Publication
(10) Pub. No.: US 2024/0355717 A1
(43) Pub. Date: Oct. 24, 2024

(54) INTEGRATED BIDIRECTIONAL FOUR QUADRANT SWITCHES WITH DRIVERS AND INPUT/OUTPUT CIRCUITS

(71) Applicant: Navitas Semiconductor Limited, Dublin (IE)

(72) Inventors: Alfred Hesener, Muenchen (DE); Daniel M. Kinzer, El Segundo, CA (US); Vincent Dessard, Mont-saint-Guibert (BE); Marco Giandalia, Marina Del Ray, CA (US)

(73) Assignee: Navitas Semiconductor Limited, Dublin (IE)

(21) Appl. No.: 18/636,035

(22) Filed: Apr. 15, 2024

Related U.S. Application Data
(60) Provisional application No. 63/496,915, filed on Apr. 18, 2023.

(51) Int. Cl. H01L 23/495; H01L 23/00; H01L 25/065; H03K 17/687

(52) U.S. Cl. CPC H01L 23/49575; H01L 23/49562; H01L 24/08; H01L 24/48; H01L 25/0652; H03K 17/6871; H01L 2224/08145; H01L 2224/08245; H01L 2224/48138; H01L 2224/48175; H01L 2924/01029; H01L 2924/0493; H01L 2924/1205; H01L 2924/13091; H01L 2924/182; H03K 2217/0063; H03K 2217/0072

(57) ABSTRACT

An electronic system is disclosed. The electronic system includes an electronic package having a base with a plurality of external terminals, and further having an electrically insulative material at least partially encapsulating the base, a controller circuit disposed within the electronic package and referenced to a first ground, a first and second driver circuits disposed within the electronic package and referenced to a second ground and arranged to receive isolated control signals from the controller circuit, and a bidirectional switch disposed within the electronic package and referenced to the second ground and arranged to receive drive signals from the first and second driver circuits. In one aspect, the first and second driver circuits are isolated from the controller circuit via capacitors, or magnetics, or optocouplers, or magneto resistors.

### CROSS REFERENCE TO RELATED APPLICATIONS

This application claims priority to U.S. provisional patent application No. 63/496,915, for “INTEGRATED BIDIRECTIONAL FOUR QUADRANT SWITCHES HAVING DRIVERS AND INPUT/OUTPUT CIRCUITS” filed on Apr. 18, 2023, which is hereby incorporated by reference in entirety for all purposes.

### FIELD

The described embodiments relate generally to power converters, and more particularly, the present embodiments relate to integrated bidirectional four quadrant switches having drivers and input/output circuits used in power converter circuits.

### BACKGROUND

Electronic devices such as computers, servers and televisions, among others, employ one or more electrical power conversion circuits to convert one form of electrical energy to another. Some electrical power conversion circuits convert a high (or low) DC voltage to a lower (or higher) DC voltage using a circuit topology called DC-DC converter. As many electronic devices are sensitive to size and efficiency of the power conversion circuit, new power converters can provide relatively higher efficiency and lower size for the new electronic devices.

### SUMMARY

In some embodiments, an electronic system is disclosed. The electronic system includes an electronic package including a base having a plurality of external terminals, and further including an electrically insulative material at least partially encapsulating the base; a controller circuit disposed within the electronic package and referenced to a first ground; a first and second driver circuits disposed within the electronic package and referenced to a second ground, and arranged to receive isolated control signals from the controller circuit; and a bidirectional switch disposed within the electronic package and referenced to the second ground and arranged to receive drive signals from the first and second driver circuits.

In some embodiments, the first and second driver circuits are isolated from the controller circuit via capacitors, magnetics, optocouplers or magneto resistors.

In some embodiments, the bidirectional switch is a first bidirectional switch and the first bidirectional switch includes a first gate terminal, a second gate terminal, a first source terminal and a second source terminal.

In some embodiments, the first source terminal is coupled to a first external terminal of the plurality of external terminals and the second source terminal is coupled to a second external terminal of the plurality of external terminals.

In some embodiments, the bidirectional switch is gallium nitride (GaN) based.

In some embodiments, the first driver circuit is coupled to the first gate terminal, and the second driver circuit is coupled to the second gate terminal.

In some embodiments, the first driver circuit is disposed on a first die, the second driver circuit is disposed on a second die, the controller circuit is disposed on a third die and the bidirectional switch is disposed on a fourth die.

In some embodiments, the fourth die further includes a sense device arranged to transmit a signal, to the controller circuit, including at least one of a magnitude and polarity of a current through the bidirectional switch.

In some embodiments, the first driver circuit is arranged to transmit a first drive signal to the first gate terminal in response to receiving a first control signal from the control circuit and the second driver circuit is arranged to transmit a second drive signal to the second gate terminal in response to receiving a second control signal from the control circuit.

In some embodiments, the system further includes a second bidirectional switch and a third bidirectional switch coupled in parallel to the first bidirectional switch.

In some embodiments, an AC power supply referenced to the second ground is coupled between the first source terminal and the second source terminal, and the second bidirectional switch and the third bidirectional switch are arranged to harvest energy from the AC power supply for operating the first and second driver circuits.

In some embodiments, the second bidirectional switch includes a depletion mode (D-mode) section and an enhancement mode (E-mode) section.

In some embodiments, the second bidirectional switch is coupled in series with an energy harvesting capacitor.

In some embodiments, the bidirectional switch is arranged to store energy harvested from a main input and use the harvested energy to provide power to the first and second driver circuits.

In some embodiments, the second bidirectional GaN switch is coupled in series with a first energy harvesting capacitor and the third bidirectional GaN switch is coupled in series with a second energy harvesting capacitor.

In some embodiments, the input/output circuit is electrically isolated from the first and second driver circuits via one or more isolation capacitors.

In some embodiments, the first driver circuit is disposed on a first die, the second driver circuit is disposed on a second die, the input/output circuit is disposed on a third die, and the first bidirectional GaN switch is disposed on a fourth die.

In some embodiments, the fourth die further includes a sense device arranged to transmit a signal, to the input/output circuit, including at least one of a magnitude and polarity of a current through the first bidirectional GaN switch.

In some embodiments, the first driver circuit is arranged to transmit a first drive signal to the first gate terminal in response to receiving a first control signal from the input/output circuit and the second driver circuit is arranged to transmit a second drive signal to the second gate terminal in response to receiving a second control signal from the input/output circuit.

In some embodiments, the second bidirectional GaN switch and the third bidirectional GaN switch are coupled in parallel to the first bidirectional GaN switch.

In some embodiments, a method of forming an electronic component is disclosed. The method includes: providing an electronic package including a base having a plurality of external terminals; forming an electrically insulative material at least partially encapsulating the base; disposing a controller circuit within the electronic package, the controller circuit referenced to a first ground; disposing a first and second driver circuits within the electronic package, the first and second driver circuits referenced to a second ground, and arranged to receive isolated control signals from the controller circuit; and disposing a bidirectional switch within the electronic package, the bidirectional switch referenced to the second ground and arranged to receive drive signals from the first and second driver circuits.

In some embodiments, a method of operating a circuit is disclosed. The method includes: providing an electronic package including a base having a plurality of external terminals, and further including an electrically insulative material at least partially encapsulating the base; providing an input/output circuit disposed within the electronic package and referenced to a first ground; providing a first and second driver circuits disposed within the electronic package and referenced to a second ground, and arranged to receive isolated control signals from the input/output circuit; providing a bidirectional switch disposed within the electronic package and referenced to the second ground and arranged to receive drive signals from the first and second driver circuits; receiving, by the input/output circuit, input data; transmitting, by the input/output circuit, intermediate data corresponding to the input data; receiving, by the first and second driver circuits, the intermediate data; producing, by the first and second driver circuits, output data corresponding to the input data; and driving, by the first and second driver circuits, the bidirectional switch with the output data.

### BRIEF DESCRIPTION OF THE DRAWINGS

FIG. 1A illustrates an integrated bidirectional four quadrant switch with drivers and input/output circuits, according to certain embodiments;

FIG. 1B illustrates an integrated bidirectional four quadrant switch with drivers and input/output circuits, where the drivers have additional connection to the substrate of the bidirectional switch, according to some embodiments;

FIG. 2 illustrates an integrated half-bridge circuit with two bidirectional four quadrant switches with drivers and input/output circuits, according to certain embodiments;

FIG. 3 illustrates an integrated bidirectional four quadrant switch with drivers, input/output circuits, and current and voltage sensors, according to certain embodiments;

FIG. 4 illustrates an integrated bidirectional four quadrant switch with drivers, current and voltage sensors, and multiple input/output circuits disposed on separate dies, according to certain embodiments;

FIG. 5 illustrates an integrated half-bridge circuit with two bidirectional four quadrant switches with drivers, current and voltage sensors, and multiple input/output circuits disposed on separate dies, according to certain embodiments;

FIG. 6A1 illustrates an integrated bidirectional four quadrant switch with self-powered drivers, according to certain embodiments. FIG. 6A2 illustrates an integrated bidirectional four quadrant switch with self-powered drivers, according to some embodiments. FIG. 6B shows a voltage across a bidirectional switch of FIG. 6A as a function of time. FIG. 6C shows a current through the bidirectional switch of FIG. 6A as a function of time. FIG. 6D shows a voltage at a particular node of the bidirectional switch of FIG. 6A as a function of time;

FIG. 7 illustrates an integrated bidirectional four quadrant switch that is similar to the integrated bidirectional switch of FIG. 3, according to certain embodiments.

FIGS. 8A to 8D show an input signal and current waveforms for the integrated bidirectional four quadrant switch of FIG. 7, according to certain embodiments;

FIG. 9A illustrates a simplified partial plan view of an electronic package that includes a bidirectional switch, a first and second driver circuits, and an input/output circuit, according to an embodiment of the disclosure. FIG. 9B illustrates a simplified partial plan view of an electronic package that includes a bidirectional switch, a first and second driver circuits, and an input/output circuit, according to some embodiment of the disclosure;

FIG. 10 illustrates a simplified partial plan view of an electronic package 1000 that includes a bidirectional switch, a first and second driver circuits, and an input/output circuit, according to an embodiment of the disclosure;

FIG. 11A illustrates a simplified partial plan view of an electronic package 1100 that includes a bidirectional switch, a first and second driver circuits, and an input/output circuit, according to an embodiment of the disclosure. FIG. 11B illustrates a simplified partial cross-sectional view of the electronic package 1100;

FIG. 12 illustrates a simplified partial plan view of an electronic package 1200 that includes a bidirectional switch, a first and second driver circuits, and an input/output circuit, according to an embodiment of the disclosure;

FIG. 13 illustrates a simplified partially transparent plan view of an electronic package 1300 in accordance with the disclosed embodiments;

FIG. 14 illustrates a simplified cross-section of the electronic package 1300 illustrated in FIG. 13;

FIG. 15 illustrate steps associated with a method of forming an electronic package, according to embodiments of the disclosure; and

FIG. 16 illustrates a method of forming an electronic package, according to embodiments of the disclosure.

### DETAILED DESCRIPTION

Circuits, devices and related techniques disclosed herein relate generally to power converters. More specifically, circuits, devices and related techniques disclosed herein relate to integrated bidirectional four quadrant switches having drivers and input/output circuits used in power converter circuits. In some embodiments, a bidirectional switch capable of operating in four quadrants of operation can be integrated with drivers and input/out circuits within one semiconductor package. In various embodiments, the bidirectional switch may be a gallium nitride (GaN) based switch having two gate terminals and two source terminals. In some embodiments, the source terminals may be floating during operation and the gate terminals may be floating during operation, therefore the driver circuits may be arranged to operate with respect to floating nodes. In various embodiments, an electronic package may include a base with a plurality of external terminals, and further including an electrically insulative material at least partially encapsulating the base. The electronic package may also include a controller circuit disposed within the electronic package and referenced to a first ground, a first and second driver circuits disposed within the electronic package and referenced to a second and third ground and arranged to receive isolated control signals from the controller. The electronic package may further include a bidirectional switch disposed within the electronic package and referenced to the second and third ground and arranged to receive drive signals from the first and second driver circuits. In some elements, the controller circuit may include input/output circuits.

In various embodiments, the driver circuits can be coupled to the gate terminals of the bidirectional switch where the driver circuits are galvanically isolated from the input/output circuits. In this way, the integrated bidirectional switch can enable use of ground-referenced input digital signals that provide control signals to the integrated bidirectional switch. Further, the integrated bidirectional switch can be employed in various applications such as, but not limited to, relatively high-power power conversion circuits. In some embodiments, a semiconductor package for an integrated bidirectional switch may include a bidirectional switch disposed on a first die, a first driver circuit disposed on a second die, a second driver circuit disposed on a third die and an input/output circuit disposed on a fourth die. In various embodiments, the first die may be GaN-based, and the second, third and fourth die may be silicon (Si) based. In some embodiments, the first, second, third and fourth die may be GaN-based.

In some embodiments, the gate terminals of the bidirectional switch may be driven separately, thereby separate driving schemes may be used for driving each gate terminal that is referenced to its corresponding source terminal, where each of the source terminals may be at highly different voltage potentials. The bidirectional switch and the driver circuits for each gate terminal can be isolated from each other as well as isolated from the input/output circuit. In various embodiments, the isolation can be achieved by capacitors, magnetics, optocouplers or magneto resistors. In some embodiments, isolation capacitors can be used to provide the isolation between the controller and the drivers/bidirectional switch. In various embodiments, the capacitors may be high-voltage capacitors. In some embodiments, the isolation capacitors may include two series connected capacitors, where one capacitor may be disposed on a die that includes the input/output (control) circuits and the other capacitor can be disposed on a die that includes the driver circuit. In various embodiments, the isolation capacitors may be completely disposed on the die that includes the driver circuit. In some embodiments, the isolation capacitors may include a plurality of cross-coupled capacitors. In various embodiments, the plurality of cross-coupled capacitors may include high voltage common centroidal layout capacitors. In some embodiments, the plurality of capacitors may be arranged in a non-cross-coupled configuration. In various embodiments, the electronic package may include one or more mismatch compensation capacitors. In some embodiments, the plurality of cross-coupled capacitors can be formed from conductive semiconductor layers.

In some embodiments, an integrated half-bridge circuit may include two bidirectional switches coupled connected in series to form the half-bridge circuit along with drivers and input/output circuits integrated within a single semiconductor package. In various embodiments, voltage sensing circuits may be included in the integrated bidirectional switch such that voltage potential between the high-side and the low-side drivers can be detected and fed back to the co-packaged drivers and to the input/output circuit and to a controller. The detected voltage potential can then be used to control a conductivity state of the bidirectional switch and/or transmitted to a microcontroller.

In various embodiments, an input/output circuit may be split into two circuits that are disposed on two separate dies within the integrated bidirectional switch package. This may be done in some applications, such as industrial applications, where the integrated bidirectional switch complies with functional safety regulations. These are applications can have relatively higher safety levels, therefore redundancy may be used for these safety-critical functions, particularly to turn off devices to protect them. Thus, two input/output circuits on two separate dies may be used in order to provide backup and reliability.

In some embodiments, the integrated bidirectional switch may include a plurality of parallel connected bidirectional switches that are arranged to self-power the high-side driver. Current approaches that provide power to an isolated high-side driver can be cumbersome because schemes such as bootstrapping may not work due to use of isolation. Disclosed embodiments of the disclosure enable use of self-powering of the isolated high-side drivers, thereby reducing system complexity and saving system costs. In various embodiments, disclosed self-powering techniques can be used to provide power to the low-side drivers and/or to the input/output circuits.

In various embodiments, a current flowing in the bidirectional switch can be sensed and the information can be used to autonomously drive the gate terminals of the bidirectional switch. In some embodiments, the information from the sensed current can be utilized to improve turn-off behavior of the switch, to improve soft turn-off and to improve soft turn-on of the switch, as well as have the bidirectional switch perform functions that otherwise may have been performed in a microcontroller. Various inventive embodiments are described herein, including methods, processes, systems, devices, and the like.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

### Integrated Bidirectional Switch

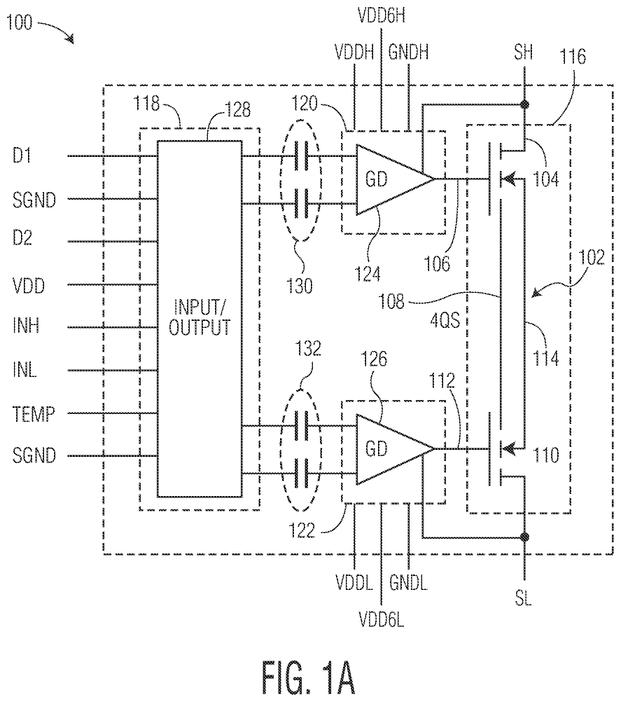

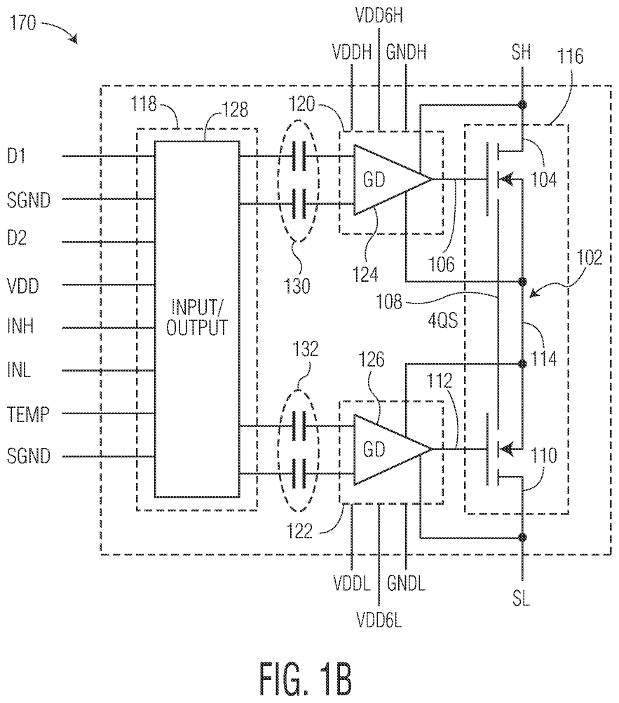

FIG. 1A illustrates an integrated bidirectional four quadrant switch with drivers and input/output circuits, according to certain embodiments. The integrated bidirectional four quadrant switch with driver and input/output circuits may also be referred to as integrated bidirectional switch. In some embodiments, the input/output circuits may include controller circuits. FIG. 1A shows an integrated bidirectional four quadrant switch with drivers and input/output circuits 100 that can include a bidirectional switch 102. The bidirectional switch 102 can include a first source terminal 104, a first gate terminal 106, a drain terminal 108, a second source terminal 110, a second gate terminal 112, and a connection to the substrate 114. The bidirectional switch 102 can be disposed on a first die 116. In some embodiments, the first die may be GaN-based.

A bi-directional switch can have an advantage being capable of operating in four quadrants of operation of a transistor, i.e., it can block voltages in both directions and current can flow in both directions in the switch. This can be useful in power converter applications where the current may flow in either direction, for example, when a free-wheeling situation in a power converter, a bidirectional switch can allow the free-wheeling current to flow from its source terminal to its drain terminal with a relatively small voltage drop across its source-to-drain terminal. The characteristics of bidirectional switches can particularly be useful in GaN-based switches where the GaN-based switch may not include a free-wheeling diode, or the free-wheeling diode may have a relatively large voltage drop when a free-wheeling current flows through it. Use of a bidirectional switch capable of four quadrant operation can improve power efficiency of the power converter. Further, the bidirectional switch can have blocking properties in both directions.

Current approaches to form a bidirectional switch by coupling two devices in series back-to-back may use relatively large die area and have relatively high series resistance because the total resistance may be twice that of each back-to-back device since they are in series. And the die area consumed may be twice of a single switch because there are two of them. Thus, there may be a factor of four increase in specific on-resistance (RSP) compared to a unidirectional switch. Use of GaN-based lateral bidirectional switch enables a reduction of RSP of the power switch, for example, a GaN-based directional switch may have an RSP that is 1.2× as compared to a unidirectional switch. This is nearly a factor of four improvement as compared to a back-to-back device. Thus, a GaN-based lateral bidirectional switch can be almost as area efficient as a unidirectional switch. The GaN-based lateral bidirectional switch can include two source terminals, two gate terminals and a common drain.

Bidirectional switches may use precise control of their gate voltages in order to operate efficiently. Further, monitoring of the voltages at the terminals of the bidirectional switch may be used to operate the bidirectional switch reliably. Embodiments of the disclosure enable integration of bidirectional switches along with associated drivers and input/output circuits in a single semiconductor package in order to provide precise control of the bidirectional switches and operate the bidirectional switches reliably. Further, embodiments of the disclosure enable precise control of voltage levels at the terminals of the bidirectional switch where the bidirectional switch operates in an isolated high-side configuration. Thus, the integrated bidirectional switch can operate reliably and efficiently, thereby saving system costs. Current approaches may use a relatively large number of external components that can result in relatively high system costs, as well as reduced reliability.

The integrated bidirectional switch 100 can further include a second die 120 having a first driver 124 and a third die 122 having a second driver 126. First driver 124 can be coupled to the first gate terminal 106 and the second driver 126 can be coupled to the second gate terminal 112. The first source terminal 104 can be connected to a pin source-high (SH) and the second source terminal 110 can be connected to a pin source-low (SL). The integrated bidirectional switch 100 can also include a fourth die 118 having an input/output circuit 128. The input/output circuit 128 can be coupled to the first driver 124 and the second driver 126 via differential isolation capacitors 130 and 132, respectively. In some embodiments, the differential isolation capacitor 130 can be formed by series connected capacitors, where one capacitor may be disposed on the second die 120 and the other capacitor disposed on the fourth die 118. In various embodiments, the differential isolation capacitor 132 can be formed by series connected capacitors, where one capacitor may be disposed on the third die 122 and the other capacitor disposed on the fourth die 118.

The integrated bidirectional switch 100 can be formed in a single semiconductor package that includes first, second, third and fourth dies. These dies may be electrically isolated from each other, thereby allowing the control of conductivity state of the bidirectional switch with input signals that are reference to separate ground levels. The single semiconductor package may be a quad-flat no-lead (QFN), small-outline-integrated-circuit package (SOIC), dual-in-line package (DIP), or any other suitable semiconductor package.

The input/output circuit 128 may include I/O pins for driver circuitry for isolated power supply (pins D1/D2/SGND), signal input and control logic (pins VDD, INH, INL, SGND), and temperature sensor and signal output (pin TEMP). The temperature can be sensed, and the sensed information can be provided to external circuitry. The input/output circuit 128 may further include transmitter circuit for transmitting driving signals across the isolation capacitors 130 and 132 to the first and second drivers, respectively. The first and second drivers 124 and 126, respectively, may include receiver circuits for receiving driving signals from the input/output circuit 128. The first and second drivers 124 and 126 may further include voltage regulator and driver circuits for driving the first gate terminal 106 and the second gate terminal 112, respectively (pins VDDH/L, VDD6H/L, GNDH/L). The voltage regulator can be used to adjust a drive voltage to the gate of the bidirectional switch. The first and second drivers 124 and 126 may further include sensor circuits for sensing voltage potential across the terminals of the bidirectional switch 102, and/or sensing a current flowing in the bidirectional switch 102. The sensed voltage and/or current can be used to provide over-voltage and over-current protection.

When INH signal goes high, the input/output circuit 128 can transmit a high signal across the isolation capacitors 130 to the first driver 124. The first driver 124 can receive the INH signal and cause a voltage at the first gate terminal 106 to go high, thereby causing the high-side of the bidirectional switch 102 to turn-on. When INL signal goes high, the input/output circuit 128 can transmit a high signal across the isolation capacitors 132 to the second driver 126. The second driver 126 can receive the INL signal and cause a voltage at the second gate terminal 112 to go high, thereby causing the low-side of the bidirectional switch 102 to turn-on. When both the high-side and the low-side of the bidirectional switch 102 are on, a current may flow from the first source terminal 104 to the second source terminal 110, or vice-versa depending on the voltage potentials at the source terminals. When both of the INH or INL signals are low, there is no current flow in the bidirectional switch 102, and the bidirectional switch is in blocking mode of operation. In some embodiments, there may be only one control input (VIN), that can drive both outputs to turn ON or OFF.

FIG. 1B illustrates an integrated bidirectional four quadrant switch with drivers and input/output circuits, according to some embodiments. FIG. 1B illustrates an integrated bidirectional four quadrant switch with drivers and input/output circuits 170 that is similar to integrated bidirectional four quadrant switch with drivers and input/output circuits 100 of FIG. 1, except that driver circuits 124 and 126 may be coupled to the substrate 114. In the illustrated embodiment, the co-packaged drivers may include a circuit to detect the state of the bidirectional switch and control the substrate potential accordingly. The substrate potential may control a back gating effect in GaN power transistors, which may cause a shift in an on-resistance of the bidirectional switch. The gate driver circuit may sense the substrate voltage with using this connection and can control the voltage of the substrate and the charge state of the substrate as a function of a sensed substrate voltage. The gate driver circuits may also control a desired state of the bidirectional switch. In some environments, other parameters may be used by the gate driver circuit such as, but not limited to, operating temperature, magnitude and/or polarity of the current in the bidirectional switch and voltage across the switch. The substrate connection can be driven with a positive or negative voltage, current, or current pulses that correspond to the required charge to be injected, to control the potential to the desired level. The voltage or current or current pulse level and length may be varied from switching cycle to switching cycle, or within one switching cycle. The gate driver circuit may use the substrate potential control to reduce ON-resistance variations due to back gating, and may also use it to temporarily increase the ON-resistance under certain circumstances, including but not limited to suppressing ringing or heating up the bidirectional switch in case of low operating temperature.

Integrated Half-Bridge with Two Bidirectional Switches

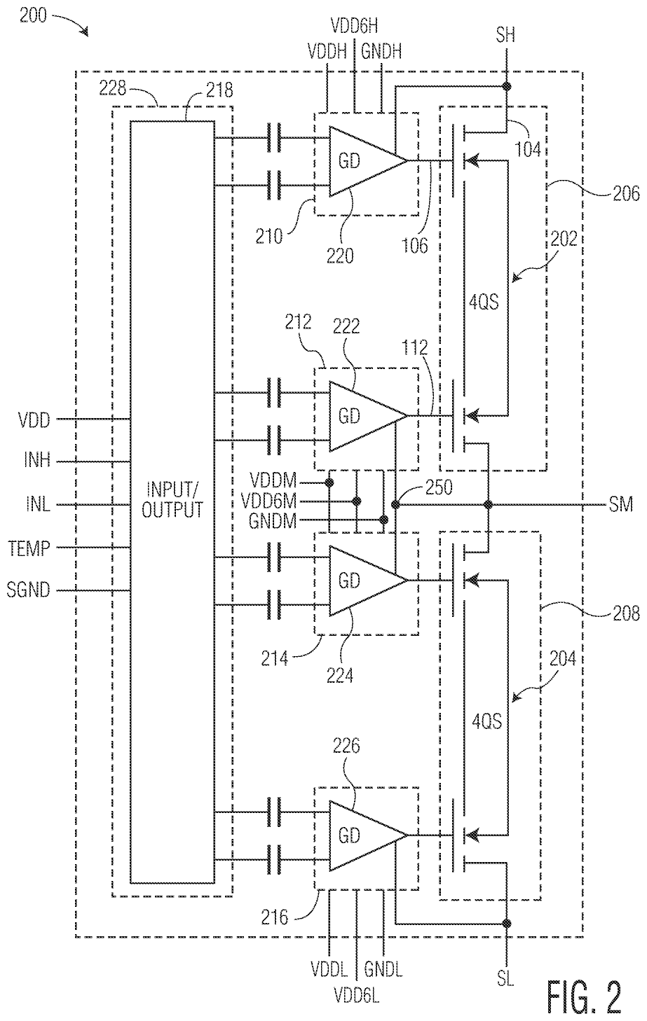

FIG. 2 illustrates an integrated half-bridge circuit with two bidirectional four quadrant switches with drivers and input/output circuits, according to certain embodiments. FIG. 2 shows an integrated half-bridge circuit 200 with two bidirectional switches coupled in series forming a half-bridge. The integrated half-bridge circuit 200 can include a first bidirectional switch 202 and a second bidirectional switch 204, where the first bidirectional switch 202 is coupled in series to the second bidirectional switch 204 at a switch node 250. The first bidirectional switch 202 may be disposed on a first die 206 and the second bidirectional switch 204 may be disposed on a second die 208. In some embodiments, the first and the second bidirectional switches 202 and 204 may be disposed on the same die. In various embodiments, the first and second dies 206 and 208, respectively, may be GaN-based.

The integrated half-bridge circuit 200 can further include a third die 210 having a first driver 220, a fourth die 212 having a second driver 222, a fifth die 214 having a third driver 224, and a sixth die 216 having a fourth driver 226. The first driver 220 can be coupled to a first gate terminal of the first bidirectional switch 202 and the second driver 222 can be coupled to a second gate terminal of the first bidirectional switch 202. The third driver 224 can be coupled to a first gate terminal of the second bidirectional switch 204 and the fourth driver 226 can be coupled to a second gate terminal of the second bidirectional switch 204. The integrated half-bridge circuit 200 can further include a seventh die 228 having an input/output circuit 218. The input/output circuit 218 can be coupled to the first, second, third and fourth drivers via differential isolation capacitors.

The integrated half-bridge circuit 200 can be formed in a single semiconductor package that includes the first, second, third, fourth, fifth, sixth and seventh dies. The single semiconductor package may be a quad-flat no-lead (QFN), small-outline-integrated-circuit package (SOIC), dual-in-line package (DIP), or any other suitable semiconductor package.

The input/output circuit 218 may include I/O pins for driver circuitry for isolated power supply (pins D1, D2, SGND), signal input and control logic (pins VDD, INH, INL, SGND) and temperature sensor and signal output (pin TEMP). The input/output circuit 218 may further include transmitter circuit for transmitting driving signals across the isolation capacitors to the first to fourth drivers. The first to fourth drivers 220 to 226, respectively, may include receiver circuits for receiving driving signals from the input/output circuit 218. They may further include voltage regulator and driver circuits for driving the gate terminals of the first bidirectional switch 202 and the second bidirectional switch 204, respectively (pins VDDH/L/M, VDD6H/L/M, GNDH/L/M). The second and third drivers 222 and 224 may share a same source connection (SM). The supply and ground nodes for the second and third drivers may be referred to as VDDM, VDD6M, GNDM, with M meaning Middle, as it is in the middle of the half bridge. The first to fourth drivers may further include sensor circuits for sensing voltage potentials across the terminals of the first and second bidirectional switches 202 and 204, respectively, and/or sensing a current flowing in the first and second bidirectional switches 202 and 204.

When INH signal goes high, the input/output circuit 218 can transmit a high signal across the isolation capacitors to the first and second drivers 220 and 222, respectively. The first and second drivers can receive the INH signal and cause a voltage at the first and second gate terminals of the first bidirectional switch 202 to go high, thereby causing the first bidirectional switch 202 to turn-on. Thus, the switch node 250 may get pulled to a voltage of the high-side. When INL signal goes high, the input/output circuit 218 can transmit a high signal across the isolation capacitors to the third and fourth drivers 224 and 226, respectively. The third and fourth drivers can receive the INL signal and cause a voltage at the first and second gate terminals of the second bidirectional switch 204 to go high, thereby causing the second bidirectional switch 204 to turn-on, thus a voltage at the switch node 250 can go to the voltage of the low-side. In some embodiments, when the gate drivers are continuously aware of the voltage polarity across each bidirectional switch, the driver driving the section of the bidirectional switch operating in reverse current can remain ON continuously, instead of switching, as the other section of the GaN of the bidirectional switch. This can reduce the dynamic current consumption of one of the drivers. The driver can be arranged to determine itself whether to remains ON or not as needed, regardless of the status of the input control signal. In this way, the driver can determine the state of operation and act accordingly. For example, to limit dynamic current consumption, when 220 and 222 determine the voltage polarity, the integrated half-bridge circuit 200 can be arranged to keep one of the switches always ON (the one that is anyway passing in reverse direction for a given polarity) and control ON/OFF only the other switch. In various embodiments, this logic can be integrated in each of the drivers 220 and 222 (and/or for drivers 224 and 226).

In some embodiments, such as in applications where the input and output power of the converter may be conveyed by a current, not a voltage, embodiments of the disclosure enable independent control of the turn-on and turn-off of the two bidirectional switches. The input current can thus be steered into the output, by turning ON the bidirectional switch 202 and simultaneously keeping OFF bidirectional switch 204. When the bidirectional switch 204 is turned ON, the current is commuting away from the load and back to returning to the input directly. This mode of operation is also called “current-source inverter”.

In various embodiments, an input power source may be connected to the terminal SH of bidirectional switch 202, and another input power source may be connected to the terminal SL of bidirectional switch 204. The load can be connected to the terminal SM. In this setup, the power to the load can be selected from either input, thus enabling operation in applications with redundant power supplies that are not allowed to fail. For example, if one of the power inputs is not available, the corresponding bidirectional switch can be turned OFF and the power supply be repaired or replaced, while the load continues to be supplied by the other power supply still in operation. Some example applications are, but not limited to, where one of the power supplies may consist of batteries, and the other power input may come from the grid, enabling continuous operation even if the grid power fluctuates or is interrupted.

Integrated Bidirectional Switch with Sensors

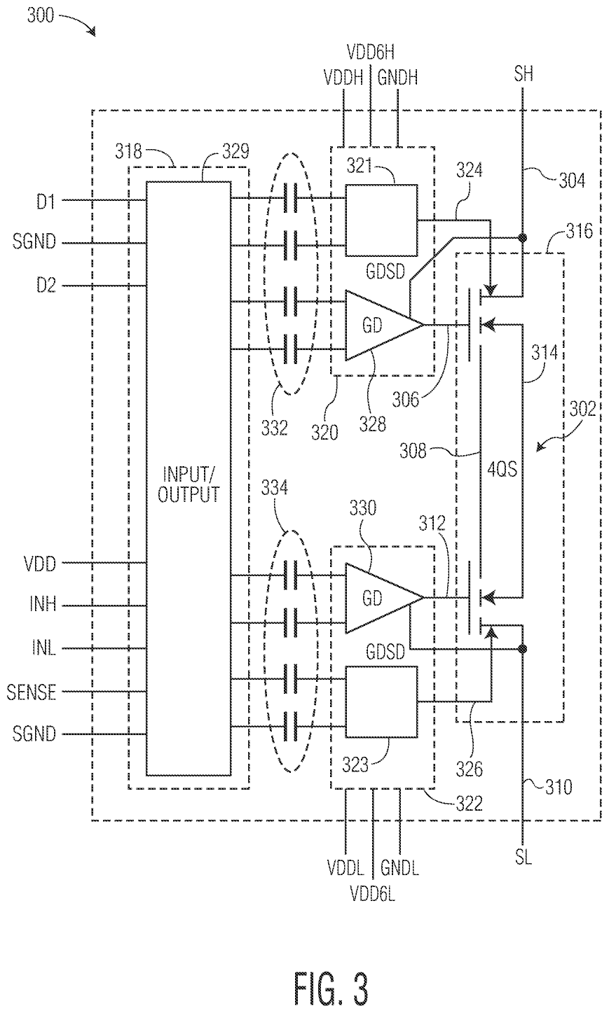

FIG. 3 illustrates an integrated bidirectional four quadrant switch with drivers, input/output circuits, and current and voltage sensors, according to certain embodiments. FIG. 3 shows an integrated bidirectional switch 300 that can include a bidirectional switch 302. The bidirectional switch 302 can include a first source terminal 304, a first gate terminal 306, a drain terminal 308, a second source terminal 310, a second gate terminal 312, and a first substrate connection 314. The bidirectional switch 302 can be disposed on a first die 316. In some embodiments, the first die may be GaN-based.

The integrated bidirectional switch 300 can further include a second die 320 having a first driver 328 and a first sensing circuit 321. The integrated bidirectional switch 300 can further include a third die 322 having a second driver 330 and a second sensing circuit 323. First driver 328 can be coupled to the first gate terminal 306. In some embodiments, the gate driver 328 may be coupled to the substrate connection 314 and can be arranged to control a voltage of the substrate, for example, clamp the substrate voltage in presence of a spurious or overvoltage condition in the substrate. The first sensing circuit 321 may be coupled to the first source terminal 304 by a connection 324 and can be arranged to sense a status of the voltage at the source terminal 304 and may be further arranged to sense a status of operation of the directional switch (for example, the section that 328 is connected to), for example, sense a polarity and a magnitude of a current flow in the directional switch 302. In some embodiments, the first sensing circuit 321 may further be arranged to sense operating temperature of the bidirectional switch.

The second driver 330 can be coupled to the second gate terminal 312. In some embodiments, the gate driver 330 may be coupled to the substrate connection 314 and can be arranged to control a voltage of the substrate, for example, clamp the substrate voltage in presence of a spurious or overvoltage condition in the substrate. A second sensing circuit 323 may be coupled to the second source terminal 310 by a connection 326 and can be arranged to sense a status of the voltage at the source terminal 310 and may be further arranged to sense a status of operation of the directional switch (for example, the section that 330 is connected to), for example sense a polarity and a magnitude of a current flow in the directional switch 302. In some embodiments, the second sensing circuit 323 may further be arranged to sense operating temperature of the bidirectional switch. The first source terminal 304 can be connected to a pin source-high (SH) and the second source terminal 310 can be connected to a pin source-low (SL). In some embodiments, operating parameters of the bidirectional switch may be used by the gate driver circuits such as, but not limited to, operating temperature, magnitude and/or polarity of the current in the bidirectional switch and voltage across the switch.

The integrated bidirectional switch 300 can also include a fourth die 318 having an input/output circuit 329. In some embodiments, the input/output circuit 329 may include control circuits. The input/output circuit 329 can be coupled to the first driver 328 and the first sensing circuit 321 via differential isolation capacitors 332, respectively. The input/output circuit 329 can be further be coupled to the second driver 330 and the second sensing circuit 323 via differential isolation capacitors 334, respectively. In some embodiments, the differential isolation capacitors 332 can be formed by series connected capacitors, where one capacitor may be disposed on the third die 322 and the other capacitor disposed on the fourth die 318.

The integrated bidirectional switch 300 can be formed in a single semiconductor package that includes first, second, third and fourth dies. These dies may be electrically isolated from each other, thereby allowing the control of conductivity state of the bidirectional switch with input signals that are reference to separate ground levels. The single semiconductor package may be a quad-flat no-lead (QFN), small-outline-integrated-circuit package (SOIC), dual-in-line package (DIP), or any other suitable semiconductor package.

The input/output circuit 329 may include I/O pins for driver circuitry for isolated power supply (pins D1/D2/SGND), signal input and control logic (pins VDD, INH, INL, SGND), and receiver circuitry for the current and voltage signals from the secondary side (pin SENSE). The input/output circuit 329 may further include transmitter circuit for transmitting driving signals across the isolation capacitors 332 and 334 to the first and second drivers, respectively. The first and second drivers 328 and 330 may include receiver circuits for receiving driving signals from the input/output circuit 329. The first and second drivers 328 and 330 may further include voltage regulator and driver circuits for driving the first gate terminal 306 and the second gate terminal 312, respectively (pins VDDH/L, VDD6H/L, GNDH/L). The voltage regulator can be used to adjust a drive voltage to the gate of the bidirectional switch. The first and second sensing circuits 321 and 323 may include sensor circuits for sensing voltage at the terminals of the bidirectional switch 302, and/or sensing a current flowing in the bidirectional switch 302.

The first and second sensing circuits 321 and 323 may further include analog-to digital (A/D) conversion circuits and transmitter circuitry for transmitting the signals corresponding to the sensed voltage and currents to the input/output circuit. The signals corresponding to the sense currents/voltages can be used for autonomous control of the bidirectional switch 302. The signals corresponding to the sensed voltage and currents can be transmitted to an external microcontroller by the input/output circuit. The signals corresponding to the sense currents/voltages can be transmitted by the input/output circuit using multiple pins, or using a single pin where the data is multiplexed. The signals corresponding to the sense currents can be used to detect when the current crossed zero from positive to negative, and/or from negative to positive flow. The input/output circuit signals can be arranged to receive a turn-on or turn-off signal and transmit it to the drivers upon sensing a relatively low voltage or current in the bidirectional switch 302 (auto-resonant operation).

An auto-resonant operation may be where in a quasi-resonant power application, the resonant nature of the load in combination with additional passive components can be used to achieve turn-on or turn-off of the power switches at low or zero voltage or current across the switch. This may be done in to reduce switching losses, and is sometimes referred to as soft switching. In contrast, switching at high voltage or current levels (also referred to as hard switching) may generate relatively high switching losses and can present elevated stress levels to the power switch. In some embodiment, the voltage and current can be sensed that enables precise determination of the voltage and current across the bidirectional switch local to the driver circuit. The sensed voltage and/or current can be used to adjust the precise switch timing to turn ON or OFF at the right moment, without intervention of a microcontroller. As the signals are available locally to the driver, they do may not have to be sent through the isolated signal transfer, subsequent connections to the system controller, and suffer from processing delays in the controller due to limited computing power. Therefore, the switching action can be signaled by the controller but the exact timing can be determined by the driver, yielding even lower losses and EMI emissions.

The input/output circuit may further be arranged to turn on the bidirectional switch when a relatively high voltage is sensed across the bidirectional switch 302 in either direction. The turn-on time can be for a pre-determined time and pulse length, or until the voltage or current in the bidirectional switch 302 have reached relatively low levels (auto-clamping).

When INH signal goes high, the input/output circuit 329 can transmit a high signal across the isolation capacitors 332 to the driver 328. The driver 328 can receive the INH signal and cause a voltage at the first gate terminal 306 to go high, thereby causing the high-side of the bidirectional switch 302 to turn-on. When INL signal goes high, the input/output circuit 329 can transmit a high signal across the isolation capacitors 334 to the second driver 330. The second driver 330 can receive the INL signal and cause a voltage at the second gate terminal 312 to go high, thereby causing the low-side of the bidirectional switch to turn-on. When both the high-side and the low-side of the bidirectional switch 302 are on, a current may flow from the first source terminal 304 to the second source terminal 310, or vice-versa depending on the voltage potentials at the source terminals. When either of the INH or INL signals are low, there is no current flow in the bidirectional switch 102, and the bidirectional switch is in blocking mode of operation.

Integrated Bidirectional Switch with Multiple Input/Output Circuits

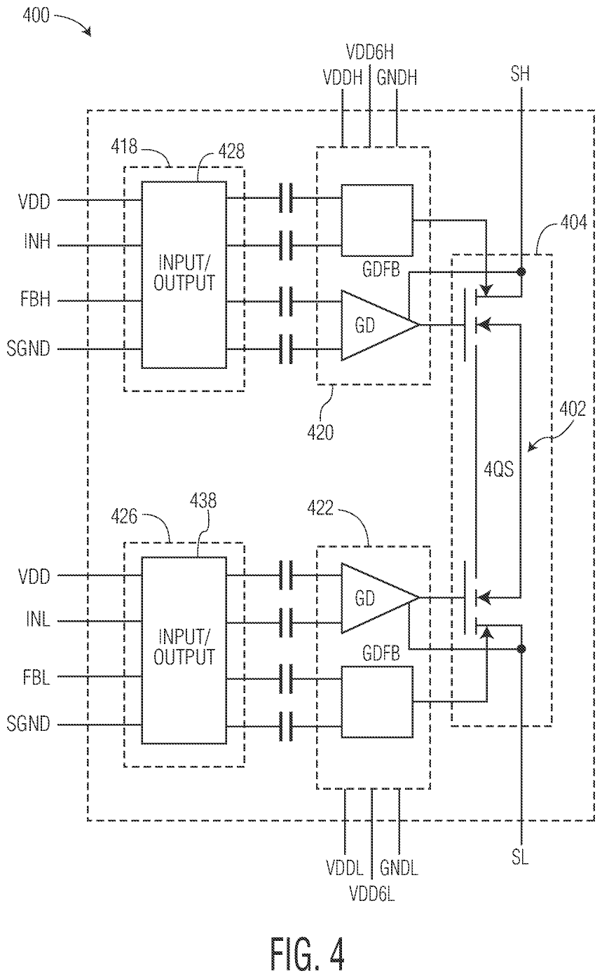

FIG. 4 illustrates an integrated bidirectional four quadrant switch with drivers, current and voltage sensors, and multiple input/output circuits disposed on separate dies, according to certain embodiments. FIG. 4 shows an integrated bidirectional switch 400 that is similar to the integrated bidirectional switch 300 except that there are two input/output circuits that are disposed on separate dies. The integrated bidirectional switch 400 can include a bidirectional switch 402. The bidirectional switch 402 can be disposed on a first die 404. In some embodiments, the first die may be GaN-based.

The integrated bidirectional switch 400 can further include a second die 420 having a first driver and a first sensing circuit. The integrated bidirectional switch 400 can further include a third die 422 having a second driver and a second sensing circuit. The integrated bidirectional switch 400 can also include a fourth die 418 having a first input/output circuit 428, and a fifth die 426 having a second input/output circuit 438. The first input/output circuit 428 can be coupled to the first driver and the first sensing circuit, and the second input/output circuit 438 can be coupled to the second driver and the second sensing circuit, respectively, via differential isolation capacitors. Use of two separate input/output circuits disposed on two separate dies within the integrated bidirectional switch package can enable some applications, such as industrial applications, where the integrated bidirectional switch complies with functional safety regulations. These applications may have a safety integrity level (SIL) such as, for example, SIL 3 or SIL 4. SIL is defined as the relative level of risk-reduction provided by a safety function. Therefore, redundancy is used for these safety-critical functions, particularly to turn off devices to protect them. Thus, two input/output circuits on two separate dies are used to provide redundancy in control and monitoring of the bidirectional switch, in order to satisfy the safety-critical functions.

The integrated bidirectional switch 400 can be formed in a single semiconductor package that includes first, second, third, fourth and fifth dies. These dies may be electrically isolated from each other, thereby allowing the control of conductivity state of the bidirectional switch with input signals that are reference to separate ground levels. The single semiconductor package may be a quad-flat no-lead (QFN), small-outline-integrated-circuit package (SOIC), dual-in-line package (DIP), or any other suitable semiconductor package.

The first and second input/output circuits 428 and 438 may include separate control circuits for both sides of the bidirectional switch 402, signal input and control logic (pins VDD, INH, INL, SGND) and receiver circuits for the status signals (FBH, FBL). The first and second input/output circuits 428 and 438 may further include transmitter circuits for transmitting driving signals to the first and second drivers across the isolation capacitors. The first and second drivers may include receiver circuits for receiving driving signals from the first and second input/output circuits 428 and 438, respectively. The first and second drivers may further include voltage regulator and driver circuits for driving the gate terminals of the bidirectional switch 402. The voltage regulator can be used to adjust a drive voltage to the gate of the bidirectional switch. The first and second sensing circuits may include sensor circuits for sensing voltage at the terminals of the bidirectional switch 402, and/or sensing a current flowing in the bidirectional switch 402.

The first and second sensing circuits may further include analog-to digital (A/D) conversion circuits and transmitter circuitry for transmitting the signals corresponding to the sensed voltage and currents to the input/output circuit. The signals corresponding to the sense currents/voltages can be used for autonomous control of the bidirectional switch 402. The signals corresponding to the sensed voltage and currents can be transmitted to an external microcontroller by the input/output circuit. The signals corresponding to the sense currents/voltages can be transmitted by the input/output circuit using multiple pins, or using a single pin where the data is multiplexed. The signals corresponding to the sense currents can be used to detect when the current crossed zero from positive to negative, and/or from negative to positive flow. The input/output circuit signals can be arranged to receive a turn-on or turn-off signal and transmit it to the drivers upon sensing a relatively low voltage or current in the bidirectional switch 402. The input/output circuit may further be arranged to turn on the bidirectional switch when a relatively high voltage is sensed across the bidirectional switch 402 in either direction. The turn-on can be for a pre-determined time and pulse length, or until the voltage or current in the bidirectional switch 402 have reached relatively low levels (auto-clamping). In various embodiments, a high voltage signal may have a range from 100 V to 1200 V, while in other embodiments it may have a range from 200 V to 800 V, while yet in other embodiments it may have a range from 500 V to 600 V. As appreciated by one of ordinary skill in the art having the benefit of this disclosure, the voltage values of the signals can be set to any suitable value.

In some embodiments, the first and second sensing circuits 321 and 323 of the integrated bidirectional switch 300 with may be configured such that a sensing switch is coupled in parallel to the bidirectional switch 302. The sensing switch can sense a magnitude and a polarity of current in the bidirectional switch 302, and feed it to an amplifier to generate a first signal. The current sense switch may be further arranged to transmit the first signal including at least one of the magnitude and polarity of the current through the bidirectional switch 302 to a driver circuit. The driver circuit can be arranged to transmit control signals to the gate terminals of the bidirectional switch based on the first signal.

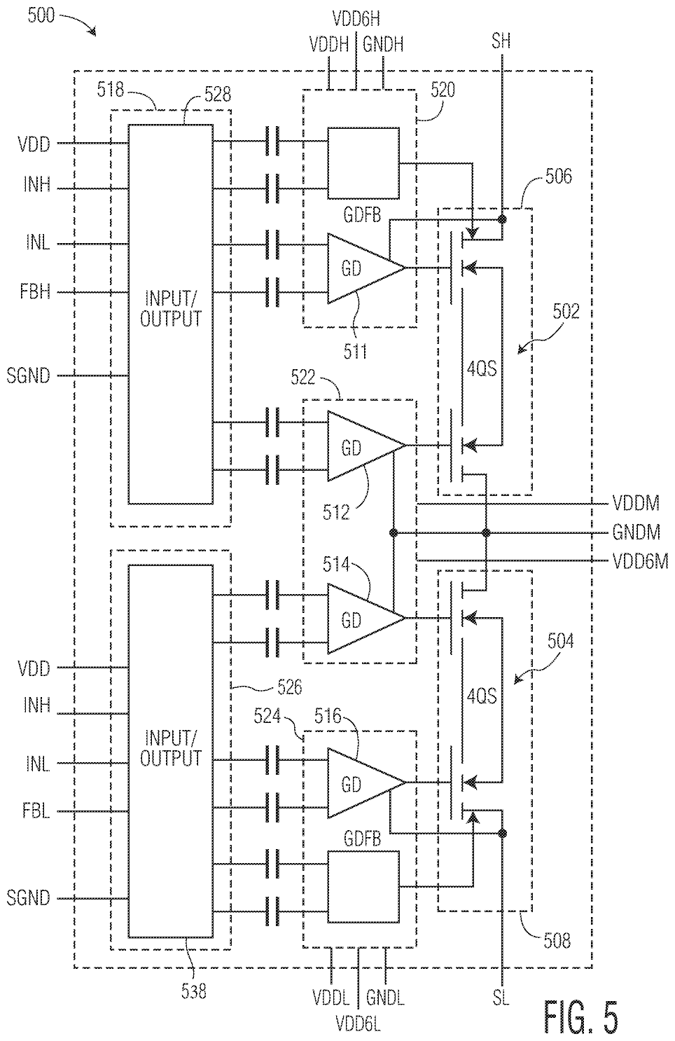

FIG. 5 illustrates an integrated half-bridge circuit with two bidirectional four quadrant switches with drivers, current and voltage sensors, and multiple input/output circuits disposed on separate dies, according to certain embodiments. FIG. 5 shows an integrated half-bridge circuit 500 that is similar to the integrated bidirectional switch 400 except that there are two bidirectional switches coupled in series to form the half-bridge circuit. In some embodiments, the two bidirectional four quadrant switches can be disposed on separate dies. In various embodiments, the two bidirectional four quadrant switches may be disposed on the same die. The integrated half-bridge circuit 500 can include a first bidirectional switch 502 coupled in series with a second bidirectional switch 504. The first bidirectional switch 502 can be disposed on a first die 506 and the second bidirectional switch 504 can be disposed on a second die 508. In some embodiments, the first and second dies may be GaN-based. In various embodiments, the first and second dies may be Si-based.

The integrated half-bridge circuit 500 can further include a third die 520 having a first driver 511 and a first sensing circuit. The integrated half-bridge circuit 500 can further include a fourth die 522 having a second driver 512 and a third driver 514. The integrated half-bridge circuit 500 can also include a fifth die 524 having a fourth driver 516 and a second sensing circuit. The integrated half-bridge circuit 500 can further include a sixth die 518 having a first input/output circuit 528, and a seventh die 526 having a second input/output circuit 538. The first input/output circuit 528 can be coupled to the first and second drivers 511 and 512, respectively, and to the first sensing circuit via differential isolation capacitors. The second input/output circuit 538 can be coupled to the third and fourth drivers 514 and 516, respectively, and to the second sensing circuit via differential isolation capacitors. Similar to the integrated bidirectional switch 400, Use of two separate input/output circuits disposed on two separate dies within the integrated bidirectional switch package can enable applications such as industrial, where the integrated bidirectional switch complies with functional safety regulations.

The half-bridge circuit 500 can be formed in a single semiconductor package that includes first, second, third, fourth, fifth, sixth and seventh dies. These dies may be electrically isolated from each other, thereby allowing the control of conductivity state of the bidirectional switch with input signals that are reference to separate ground levels. The single semiconductor package may be a quad-flat no-lead (QFN), small-outline-integrated-circuit package (SOIC), dual-in-line package (DIP), or any other suitable semiconductor package.

Integrated Bidirectional Switch with Self-Powered Drivers

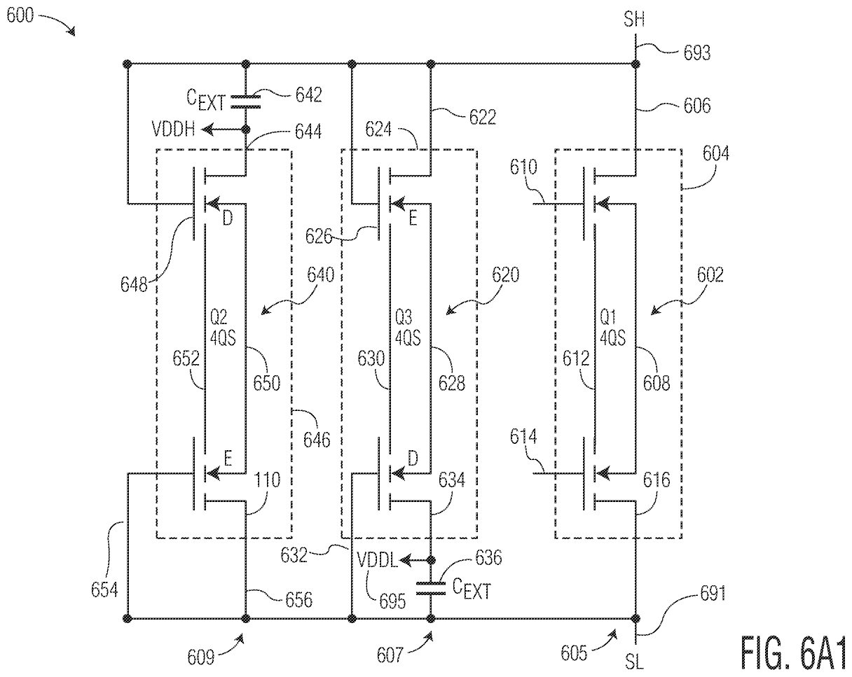

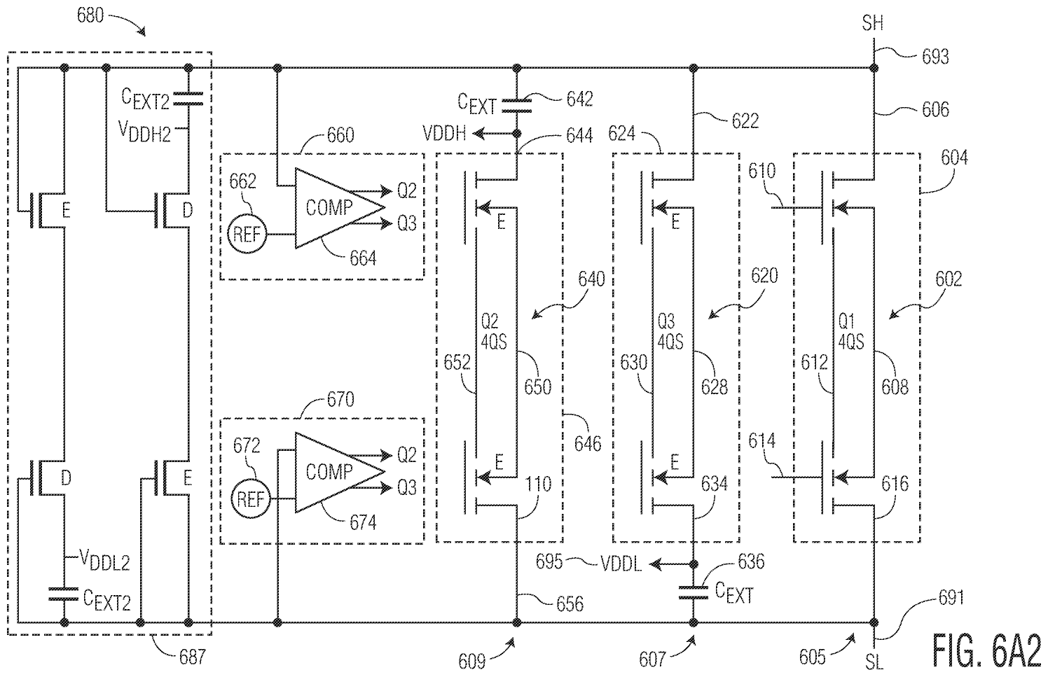

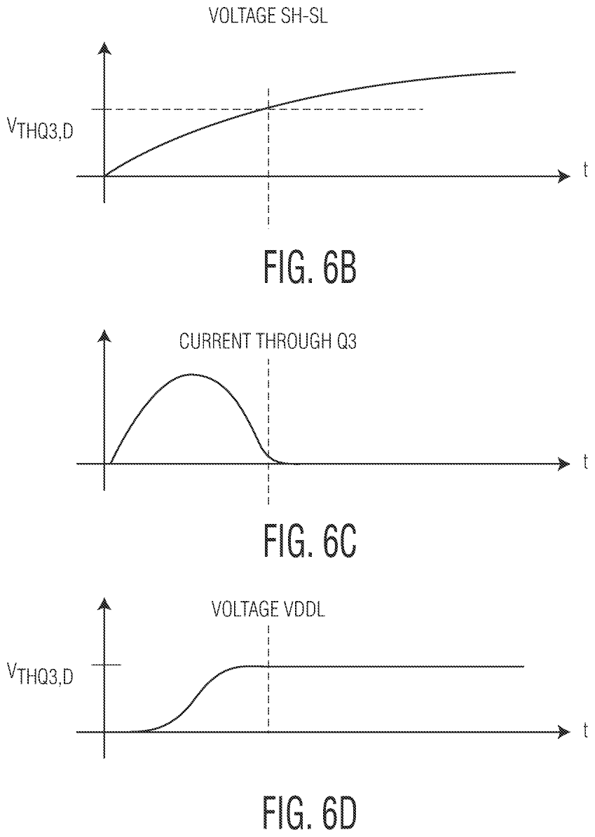

FIG. 6A1 illustrates an integrated bidirectional four quadrant switch with self-powered drivers, according to certain embodiments. FIG. 6A1 shows an integrated bidirectional switch with self-powered drivers 600 that can include a bidirectional switch stage 605, a bidirectional switch stage 607 and a bidirectional switch stage 609. The bidirectional switch stage 605 can include a bidirectional switch 602 that may have an enhancement-mode (E-mode) upper section and an E-mode lower section. The bidirectional switch stage 607 can include a bidirectional switch 620 that may have an E-mode upper section and a D-mode lower section. The bidirectional switch stage 609 can include a bidirectional switch 640 that may have a D-mode upper section and an E-mode lower section. In some embodiments, the bidirectional switch 602, bidirectional switch 620 and the bidirectional switch 640 may be disposed on the same GaN-based die. In various embodiments, the bidirectional switch 602, bidirectional switch 620 and the bidirectional switch 640 may be disposed on the separate GaN-based die. In some embodiments, the bidirectional switch 602, bidirectional switch 620 may be disposed on the same die while the bidirectional switch 640 is disposed on a separate die. Other combinations of the disposing of the bidirectional switches on various GaN-based die are within the scope of this disclosure.

FIG. 6A2 illustrates an integrated bidirectional four quadrant switch with self-powered drivers with E-mode upper and lower sections, according to some embodiments. FIG. 6A2 shows an integrated bidirectional switch with self-powered drivers 680. As illustrated in FIG. 6A2, the bidirectional switch 620 may include an E-mode upper section and an E-mode lower section. In various embodiments, the bidirectional switch 640 may include an E-mode upper section and an E-mode lower section. In certain embodiments, the bidirectional switches 602, 620 and 640 may be GaN-based. In some embodiments, each of the bidirectional switches 602, 620 and 640 can be disposed on a single die that is isolated from the other dies. In various embodiments, the bidirectional switches 602, 620 and 640 can all be disposed on a single die. In some embodiments, a startup supply circuit 687 can be coupled to bidirectional switch with self-powered drivers 680, where a supply for die 660 and die 670 can be arranged to provide supply power during startup of the circuit.

In the bidirectional switch with self-powered drivers 600 and 680, the bidirectional switch stage 605 can perform the switching functions while bidirectional switch stage 607 and bidirectional switch stage 609 may be arranged to self-power the drivers for the bidirectional switch stages 605, 607 and 609. For example, the bidirectional switch stage 605 can be used in an inverter, as an AC relay, or in other applications. The size of the bidirectional switch 602 can be relatively large compared to the bidirectional switches 620 and 640. In some embodiments, the bidirectional switches 620 and 640 can have relatively high on-resistance (RDSON) and may carry relatively low currents.

In the illustrated embodiment, the drivers driving gate terminals of the bidirectional switch 602, 620 and 640 can be self-powered, i.e., the drivers can operate without having a power supply. This can be advantageous when the drivers are isolated because providing a power supply for an isolated high-side driver can be cumbersome. Current approaches, such as bootstrapping techniques, may use relatively large number of external components to provide the high-side isolated drivers with a power supply which can increase system costs and can make the system less reliable. Embodiments of the disclosure enable self-powering the drivers for bidirectional switches thereby reducing system complexity and costs, and increasing the reliability of the system. Further, embodiments of the disclosure can integrate self-powered drivers with bidirectional switches along with input/output circuits in a single semiconductor package, thereby reducing system costs and enabling relatively high operational frequencies.

In some embodiments, energy from a first source to a second source of a bidirectional switch can be harvested to power drivers driving the bidirectional switch. The energy may be harvested and stored on an energy harvesting capacitor during a time period when input voltage is high and can be used to power the drivers when the input voltage is zero or is not available. Thus, the energy may be harvested when an input voltage is within a certain acceptable range such that the energy harvesting may not draw excessive power by harvesting the energy from high voltage. Embodiments of the disclosure enable harvesting the energy from source to source and taking the energy for the drive function when the input voltage is within an acceptable range. In some embodiments, such as AC applications where the input voltage may be a sinusoidal, harvesting of energy can be performed when the input voltage is close to zero where the input voltage is high enough to deliver a charge for the drive function but not too high to cause excess power loss. In various embodiments, energy from a first source to a second source of a bidirectional switch can be harvested to power drivers for the bidirectional switch. In some embodiments, the first and second sources may be coupled to AC mains.

The bidirectional switch 602 can have a source terminal 606 coupled to a high-side source pin 693 (SH), a gate terminal 610, a drain terminal 612, a substrate connection 608, a gate terminal 614 and a source terminal 616 coupled to a low-side source pin 691 (SL). A first driver circuit can be coupled to the gate terminal 610 and a second driver circuit can be coupled to the gate terminal 614. The bidirectional switch 602 can be disposed on a first die 604. The bidirectional switch 620 can be a hybrid switch, i.e., the upper section can be an E-mode and the lower section may be a D-mode. The bidirectional switch 620 can a have a source terminal 622 coupled to a high-side source pin, a gate terminal 626, a drain terminal 630, a substrate connection 628, a gate terminal 632 and a source terminal 634. The bidirectional switch 620 can be disposed on a second die 624. The source terminal 634 can be coupled to an energy harvesting capacitor 636, and the energy harvesting capacitor 636 can be coupled to the low-side source pin. The bidirectional switch 640 can be a hybrid switch, i.e., the upper section can be a D-mode and the lower section may be an E-mode. The bidirectional switch 640 can a have a source terminal 644 coupled to an energy harvesting capacitor 642 where the energy harvesting capacitor 642 may be coupled to the high-side source pin. The bidirectional switch 640 can a further include a gate terminal 648, a drain terminal 652, a connection to substrate 650, a gate terminal 654 and a source terminal 654 that is coupled to SL. The bidirectional switch 640 can be disposed on a third die 646.

As illustrated in FIG. 6A2, the integrated bidirectional switch with self-powered drivers 680 can further include a first comparator 664 disposed on a fourth die 660 and a second comparator 674 dispose on a fifth die 670. The fourth die 660 can further include a reference voltage 662 that is provided to the input of the comparator 664. The fifth die 670 can further include a reference voltage 672 that is provided to the input of the comparator 664. The fourth and fifth dies can further include an impedance divider circuit that is arranged to measure a voltage difference between the source terminals 622 and 634, and source terminals 644 and 656, respectively. Voltage references 662 and 672 can be used to determine proper switching levels of the comparators 664 and 674. The comparator 664 can generate signals that are sent to relatively small gate drivers (disposed on fourth die) to drive gate terminals 626 and 648. The comparator 674 can generate signals that are sent to relatively small gate drivers (disposed on fifth die) to drive gate terminals 632 and 654. In some embodiments, gate terminal 654 may be coupled to the source terminal 656 and gate terminal 626 may be coupled to source terminal 622. In this way, the gate terminals of the D-mode sections are controlled by the comparator/driver circuits. Further, the signals generated by the comparators 664 and 674 can be used to provide status signals for control of the bidirectional switch 602. In some embodiments, the fourth die can also include the driver circuit for the gate 610, while in various embodiments the fifth die can also include the driver circuit for the gate 614. The fourth die may be powered by VDDL versus SL and the fifth die may be powered by VDDH versus SH.

In some embodiments, a size of the energy harvesting capacitor 636 can be, for example, one microfarad. The energy harvesting capacitor 636 can be charged by the bidirectional switch 620 which may have, for example, 100 milliohms of on-resistance. Therefore, the charging time would be on the order of 10 to 100 nanoseconds. A size of the bidirectional switch 620 can be selected so that the charging time of the energy harvesting capacitor is set properly such that it is fast and such that there is relatively small amount of current flowing through the bidirectional switch 620. Similar to bidirectional switch 620, the size of the bidirectional switch 640 can be selected such that it can generate an appropriate charging time for the energy harvesting capacitor 642. As appreciated by one of ordinary skill in the art having the benefit of this disclosure, the size of the energy harvesting capacitors can be set to any suitable value. Further, the value of the on-resistance of the bidirectional switches that are arranged to charge the energy harvesting capacitors can be set to any suitable value.

As illustrated in FIG. 6A1, in some embodiments, the gate terminal 626 of the bidirectional switch 620 may be coupled to the source terminal 622. Thus, the upper section of the bidirectional switch 620 may be in a diode-connected configuration. In this way, the energy harvesting capacitor 636 can be charged to a threshold voltage of the D-mode upper section, and would subsequently turn itself off automatically. In various embodiments, such as but not limited to FIG. 6A2, the gate terminal 626 of the bidirectional switch 620 can be coupled to an output of the comparator 664, where the comparator 664 would control the charge on the energy harvesting capacitor and where the comparator can turn on or off the gate terminal 626 depending on what the voltage levels. In this way, the energy harvesting capacitor 636 can be charged to voltage levels different from the threshold voltage of the D-mode upper section.

In some embodiments, such as but not limited to FIG. 6A1, the gate terminal 654 of the bidirectional switch 640 may be coupled to the source terminal 656. Thus, the lower section of the bidirectional switch 640 may be in a diode-connected configuration. In this way, the energy harvesting capacitor 642 can be charged to a threshold voltage of the D-mode lower section, and would subsequently turn itself off automatically. In various embodiments, the gate terminal 654 of the bidirectional switch 640 can be coupled to an output of the comparator 674, where the comparator 674 may control the charge on the energy harvesting capacitor 642. In some embodiments, the comparator can turn on or off the gate terminal 654 depending on what the voltage levels. In various embodiments, 648 can be controlled to stop or not charge capacitor 642. In various embodiments, the energy harvesting capacitor 642 can be charged to voltage levels different from the threshold voltage of the lower section.

In some embodiments, for an input voltage that is sinusoidal, the voltage levels at SH and SL can be alternating. The voltage at SH can be positive where the voltage at SL is negative, or the voltage at SH can be negative where the voltage at SL is positive. When a voltage at the drain terminal 622 gets to a level that is in a predetermined voltage range, for example 12 to 18 volts, the bidirectional switch 620 can be turned on and can charge the energy harvesting capacitor 636 to a voltage, for example, 18 volts. When the voltage gets higher, then the bidirectional switch 620 may be turned off, thus it may act like a window comparator that will charge the capacitor only when that voltage difference between SH and SL is in the right range. During a time period when the bidirectional switch 620 is on, the energy harvesting capacitor 636 can be charged, thus the energy harvesting capacitor 636 and the bidirectional switch 620 are sized such that there is sufficient charge on that capacitor to power the circuits during a time when the voltage is not in the correct range. As appreciated by one of ordinary skill in the art having the benefit of this disclosure, the predetermined voltage range can be set to any suitable value.

In some embodiments, when a voltage at the source terminal 656 gets to a predetermined level, for example 12 to 18 volts, the bidirectional switch 640 can be turned on and can charge the energy harvesting capacitor 642 to a voltage of, for example, 18 volts. When the voltage gets higher, then the bidirectional switch 640 may be turned off, thus it may act like a window comparator that will charge the capacitor 642 only when that voltage difference between SH and SL is in the right range. During a time period when the bidirectional switch 640 is on, the energy harvesting capacitor 642 can be charged, thus the energy harvesting capacitor 642 and the bidirectional switch 640 are sized such that there is sufficient charge on that capacitor to power the circuits during a time when the voltage is not in the correct range.

Self-Powered Operation Using Bidirectional Switches with E-Mode and D-Mode Sections

The section above described the operation of the bidirectional switch with self-powered drivers 600 when all stages are enhancement mode. In the above section, the comparator 664 can turn off the bidirectional switch 620 when the input voltage is a predetermined window, and for inverse polarity, the comparator 674 can turn off the bidirectional switch 640 when the input voltage is a predetermined window. In some embodiments, the energy harvesting capacitors 636 and 642 may have no charge to begin with. Embodiments of the disclosure can enable power up from zero charge on the energy harvesting capacitor by utilizing depletion mode (D-mode) in lower section of bidirectional switch 620 and depletion mode in the upper section of the bidirectional switch 640.

For example, the D-mode section may have a threshold voltage of −20 V. Therefore, the D-mode section would conduct when the gate terminal is tied to the source terminal, and it would charge up the energy harvesting capacitor to a voltage of 20 V, at which point it would turn itself off because the source voltage would then be at 20 V, gate-to-source voltage would be −20, and the D-mode section would then turn itself off. During this time period, the source terminal may be at a higher potential compared to the drain terminal and the transistor would be operating in reverse-conduction. The D-mode lower section of the bidirectional switch 620 and the D-mode upper section of the bidirectional switch 640 can enable startup. The E-mode sections on the opposite end can be configured in a diode connected arrangement where the gate and source terminals are coupled together, and the E-mode section may act as rectifying the input signal such that it is conductive when the energy harvesting capacitor is being charged, and can act in blocking mode when the circuit is preventing discharge of the energy harvesting capacitor. As appreciated by one of ordinary skill in the art having the benefit of this disclosure, the threshold voltage of the D-mode section can be set to any suitable value. In some embodiments, bidirectional switch with self-powered drivers 600 can use bidirectional switches with D-mode sections which can enable the circuit to function without using comparators.

### Start-Up Operation

When capacitor 636 is discharged, the gate terminal 632 of bidirectional switch 620 (lower section; D-mode) can be connected to node SL, therefore an effective gate-source voltage of the lower section of bidirectional switch 620 can be the same as the voltage across capacitor 636 with a reversed polarity. As the voltage SH-SL increases (FIG. 6B), bidirectional switch 620 can start conducting current (FIG. 6C), because a depletion-mode switch can conduct current even when there is zero volt across the gate to source terminals. Therefore, the voltage 695 (VDDL) can increase (FIG. 6D) and reach a level of a threshold voltage of the lower section of the bidirectional switch 620 V_{THQ3,D}. In some embodiments, V_{THQ3,D} may have a value of 18 to 20V. When voltage 695 (VDDL) reaches the threshold voltage V_{THQ3,D}, the lower section of the bidirectional switch 620 (D-mode) may be turned off, and the current through bidirectional switch 620 decreases to zero, even though the voltage SH-SL continues to rise. During this event the upper section of the bidirectional switch 620, which is connected as diode (gate tied to source), may be in reverse conduction, as the voltage at the source terminal can be higher than the voltage at the drain terminal 630. In some embodiments, a turn-on can occur when a voltage difference is in a range of, for example, 12-18V and when the capacitors that are being charged as a consequence of the voltage being in the range of, for example, 12-18V.

When the voltage SH-SL is decreasing again, the lower section of the bidirectional switch 620 (D-mode) may re-enter conduction and recharge capacitor 636. When the voltage SH-SL changes polarity, the upper section of the bidirectional switch 620 can be in blocking state and no current may flow, thus preventing the discharge of capacitor 636 during this period. The circuits coupled to capacitor 636 may discharge the capacitor 636, and voltage 695 (VDDL) can decrease. For each subsequent cycle of the voltage SH-SL, the capacitor 636 can be recharged to the threshold voltage V_{THQ3,D}, where this next charging period may be shorter than during initial charging at startup. In particular, the flow of current will start later, as the remaining voltage on capacitor 636 can provide a larger value from which to start from. The bidirectional switch 620 may be sized so that the current delivered to capacitor 636 is relatively high enough to maintain VDDL above the appropriate supply voltage to the connected circuits. The bidirectional switch 620 can be sized small enough so as to operate as a current source.

Table 1 further describes an example method of operation of bidirectional switch with self-powered drivers 600 (or 680), particularly operating bidirectional switches 620 and 640.

TABLE 1

| | Input voltage SH-SL | | | |
|---|---|---|---|---|
| | + | + | − | − |
| Gate | Bidirectional | Bidirectional | Bidirectional | Bidirectional |
| | switch 640 Upper | switch 620 Upper | switch 640 Upper | switch 620 Upper |
| Status | OFF or ON | ON (reverse | ON till VDDH | OFF |
| | depending on the | mode diode) | reaches Vth of the | |
| | VDDH voltage vs. | | D-Mode | |
| | the Vth of the | | | |
| | D-mode | | | |
| Gate | Bidirectional | Bidirectional | Bidirectional | Bidirectional |
| | switch 640 Lower | switch 620 Lower | switch 640 Lower | switch 620 Lower |
| Status | OFF | ON till VDDL | ON (reverse | OFF or ON |
| | | reaches Vth of the | mode diode) | depending on the |
| | | D-Mode | | VDDL voltage |
| | | | | vs. the Vth of the |
| | | | | D-mode |

The control logic can also be rephrased as: 1) When a voltage at the “other” source of the bidirectional switch is negative with respect to the local source, turn both sections of the bidirectional switch off; 2) When the voltage at the “other” source is positive with respect to the local source, turn the bidirectional switch referenced to the local source OFF; 3) When the voltage at the “other” source is positive with respect to the local source, turn the capacitor-connected bidirectional switch on if the voltage is in between a predetermined range (e.g., 12 to 18 V).

Table 2 further describes an example method of operation of bidirectional switch with self-powered drivers 600 (or 680), showing status of the comparator output. Table 2 provides examples of comparator signals that can be used by the controller to determine the bidirectional switch status.

TABLE 2

| SH-SL | Comparator Output Status |
|---|---|
| >18 V | High positive voltage across the switch; |
| | Switch is blocking. |
| 12 to 18 V | Charging the supply cap possible |
| 5 to 12 V | Voltage too low for charging; |
| | Confirm switch is on |
| −5 to 5 V | Zero crossing or loss of high voltage; |
| | Confirm switch is on |
| <5 V | Negative voltage across the switch; |
| | Switch is reverse-conducting. |

As appreciated by one of ordinary skill in the art having the benefit of this disclosure, the voltage values for SH-SL can be set to any suitable value.

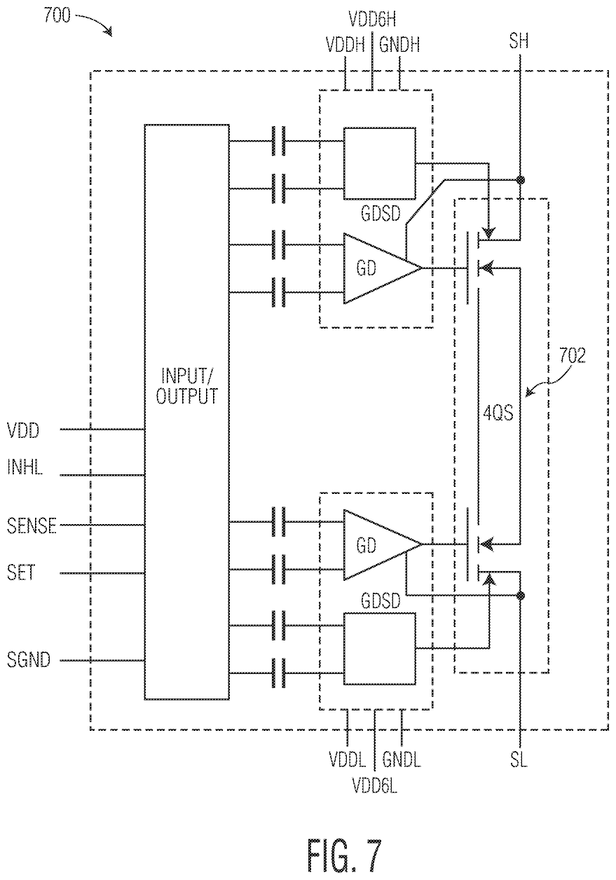

FIG. 7 illustrates an integrated bidirectional four quadrant switch 700 that is similar to the integrated bidirectional switch 300, according to certain embodiments. The integrated bidirectional four quadrant switch 700 may include an input/output circuit having include I/O pins for signal input and control logic (pins VDD, INHL, SET, SGND), transmitter circuitry for driving signals, receiver circuitry for the current and voltage signals from the secondary side (pin SENSE) and signal processing circuitry for current control. The control circuit can receive the sensed current information from one or both ends of the bidirectional switch, and may process the current information signal along with the input signal to control the bidirectional switch 702. In particular, the control circuit can implement a turn-on or turn-off sequence so as to turn on or off one end of the bidirectional switch before the other. It could also decide to keep the switch operating in reverse direction always ON while toggling the other switch ON/ODD accordingly to the INHL input control.

When the current through the bidirectional switch 702 gets to be relatively high, the control circuit can turn off the bidirectional switch 702 (overcurrent protection). In some embodiments, the turn-off can be latched, so that a power supply cycle or reset signal can be used for a new turn-on. In some embodiments, the turn-off can be slow, to make a soft turn-off, so that no voltage surge can occurs due to high energy accumulated in parasitic inductors of the power switches. In various embodiments, the turn-off can be for a relatively short time period, such that the next rising edge may turn the switch back on. In some embodiments, the turn-off can be staggered, where the turn-off sequence consists of pulses with configurable frequency that are progressively getting relatively shorter, to reach zero during a predefined time period. In various embodiments, the similar technique can be used to turn on or off the bidirectional switch 702 upon a turn-on/off signal at the input.

The control circuit can also implement a configurable current rise or fall time, using the same scheme of staggered pulses, upon turn-on and turn-off. The current rise/fall times may be different for turn-on and turn-off, and may depend on other parameters such as temperature or current or voltage levels. The pulses during current ramp-up may be shortened if the current is approaching or exceeding maximum level. The pulses during current ramp-down may be blanked if the current already has reached zero.

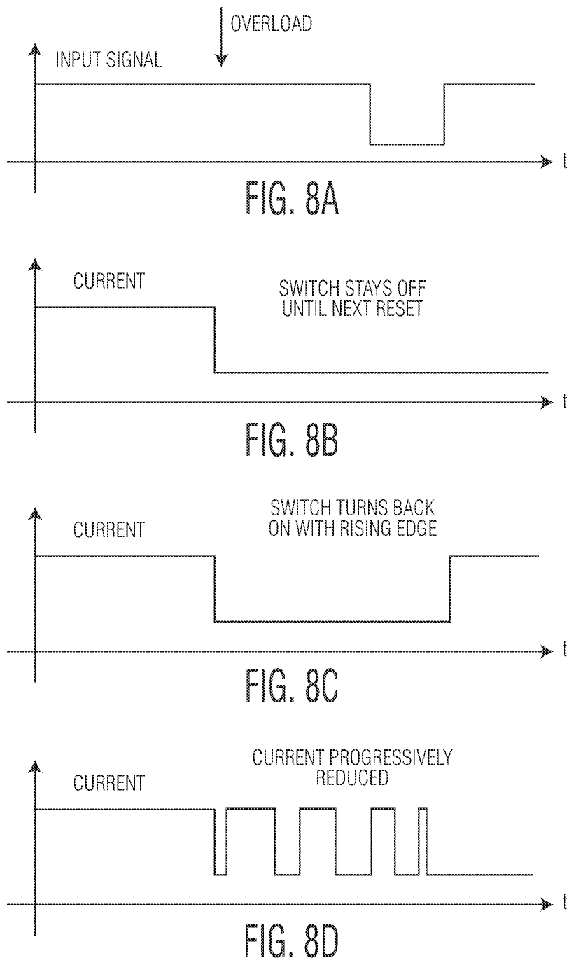

FIGS. 8A to 8D show an input signal and current waveforms for the integrated bidirectional four quadrant switch 700, according to certain embodiments. Using the sensed current information, the turn-off or turn-on of the bidirectional switch 702 can be configured correspondingly. The turn-off or turn-on can be hard or staggered, depending on the load conditions, and the parasitic inductance and capacitance in the system. FIG. 8A shows an input signal. FIG. 8B shows turn-off in a severe overload situation, where another turn-on is not allowed until the load is cleared. FIG. 8C shows a mild overload situation, or current-limited repetitive turn-on. This can be used in safety-critical applications. FIG. 8D shows controlled current ramp-up or ramp-down to prevent current spikes (only ramp-down shown).

### Integrated Semiconductor Packages

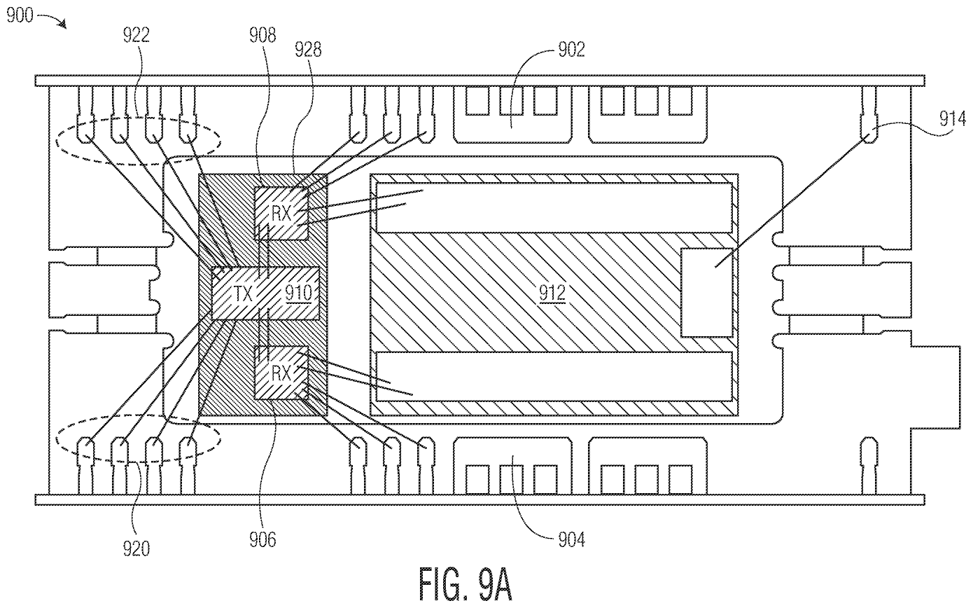

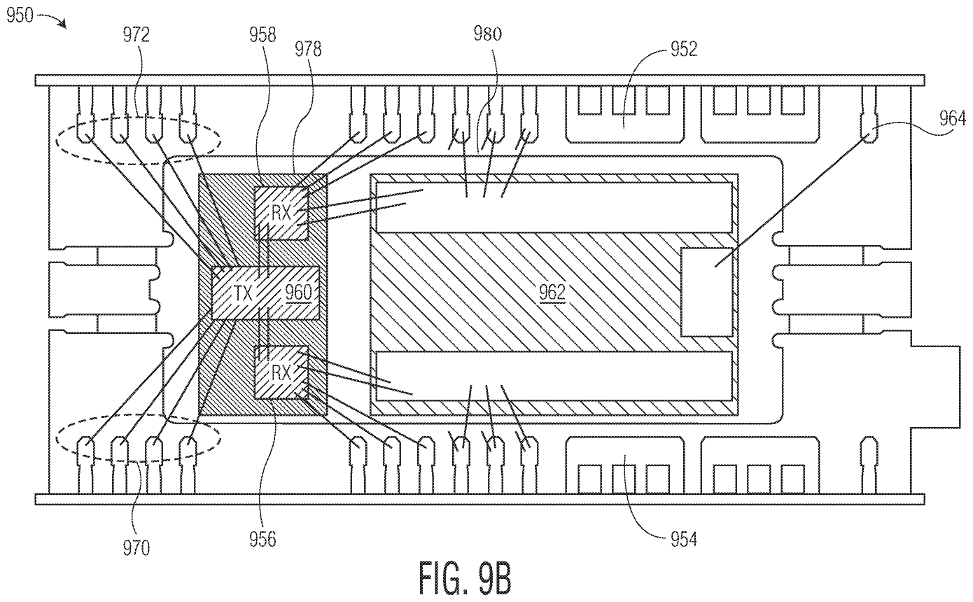

FIG. 9A illustrates a simplified partial plan view of an electronic package 900 that includes a bidirectional switch, a first and second driver circuits, and an input/output circuit, according to some embodiments of the disclosure. As shown in FIG. 9A, the bidirectional switch can be disposed on a first die, first driver circuit can be disposed on a second die, second driver circuits can be disposed on a third die, and the input/output circuit can be disposed on a fourth die. The first, second, third and fourth dies are separate dies and can be arranged in a top-cooled shrink small-outline package (SSOP). In some embodiments, the first die can further include a second bidirectional switch and a third bidirectional switch. The second and third bidirectional switches can be arranged to harvest energy from an input signal at an input terminal (S1 to S2) and used the harvested energy to supply power to the first and second driver circuits. In various embodiments, the second bidirectional switch can have a D-mode section and an E-mode section. In some embodiments, the third bidirectional switch can have a D-mode section and an E-mode section.

The electronic package 900 can include a bidirectional switch 912, a first driver circuit 906, a second driver circuit 908 and an input/output circuit 910. The bidirectional switch 912 can have a substrate connection that is coupled to a package pin 914. The first and second driver circuits 906 and 908, respectively, can be coupled to the bidirectional switch 912 by wirebonds. The first and second driver circuits 906 and 908, respectively, can also be coupled to the input/output circuit 910 by wirebonds. The first and second driver circuits 906 and 908, respectively, can also be coupled to their corresponding package pins by wirebonds. The input/output circuit 910 circuit can be coupled to its corresponding package pins 920 and 922 by wirebonds. Pins 902 can be coupled to the first source (S1) of the bidirectional switch 912 and pins 904 can be coupled to the second source (S2) of the bidirectional switch 912. The electronic package 900 can also include a spacer 928 that may be formed from, for example, Alumina (Al₂O₃) or aluminum nitride, or an insulating tape. The spacer 928 can be electrically isolating. In some embodiments, the spacer may have low thermally conductive characteristics. Most of the heat dissipation can occur by the bidirectional switch through the top. The spacer can be disposed under the first and second driver circuits 906 and 908, respectively, and the input/output circuit 910 dies, thereby isolating the first and second driver circuits 906 and 908, respectively, and the input/output circuit 910 from the bidirectional switch 912, as well as isolating the first driver circuit 906 from the second driver circuit 908. An electrically insulative encapsulant can be formed around the electronic package 900. 912 could include several bidirectional switches in parallel, 2 of them with D- and E-Mode devices for implementing energy harvesting. In this case, the package 900 might have additional low power pins for connecting external decoupling capacitors 636 and 642.

FIG. 9B illustrates a simplified partial plan view of an electronic package 950 that includes a bidirectional switch, a first and second driver circuits, and an input/output circuit, according to some embodiment of the disclosure. The electronic package 950 is similar to the electronic package 900 with additional three connections 980 per side. The electronic package 950 can be used to package the circuit illustrated in FIG. 6A1 or in FIG. 6A2. The three connections 980 in the electronic package 950 may be used for connection of gates indicated by “D” and “E” transistor end, as well as where the source of the “D” is connected to CENT. In some embodiments, the bidirectional switches 620 and 640 may be disposed on the same die as the main bidirectional switch 602. In various embodiments, the bidirectional switches 620 and 640 may be disposed on separate dies.

The electronic package 950 can include a bidirectional switch 962, a first driver circuit 956, a second driver circuit 958 and an input/output circuit 950. In some embodiments, the input/output circuit may include a controller. The bidirectional switch 962 can have a substrate connection that is coupled to a package pin 964. The first and second driver circuits 956 and 958, respectively, can be coupled to the bidirectional switch 962 by wirebonds. The first and second driver circuits 956 and 958, respectively, can also be coupled to the input/output circuit 960 by wirebonds. The first and second driver circuits 956 and 958, respectively, can also be coupled to their corresponding package pins by wirebonds. The input/output circuit 910 circuit can be coupled to its corresponding package pins 970 and 972 by wirebonds. Pins 952 can be coupled to the first source (S1) of the bidirectional switch 962 and pins 954 can be coupled to the second source (S2) of the bidirectional switch 962. The electronic package 950 can also include a spacer 978 that may be formed from, for example, Alumina (Al₂O₃) or aluminum nitride, or an insulating tape. The spacer 978 can be electrically isolating. In some embodiments, the spacer may have low thermally conductive characteristics. Most of the heat dissipation can occur by the bidirectional switch through the top. The spacer can be disposed under the first and second driver circuits 956 and 958, respectively, and the input/output circuit 960 dies, thereby isolating the first and second driver circuits 956 and 958, respectively, and the input/output circuit 960 from the bidirectional switch 962, as well as isolating the first driver circuit 956 from the second driver circuit 958. An electrically insulative encapsulant can be formed around the electronic package 950. 962 could include several bidirectional switches in parallel, two of them with depletion mode and enhancement mode devices used for energy harvesting functions. The package 950 may include additional low power pins for connecting external decoupling capacitors 636 and 642.

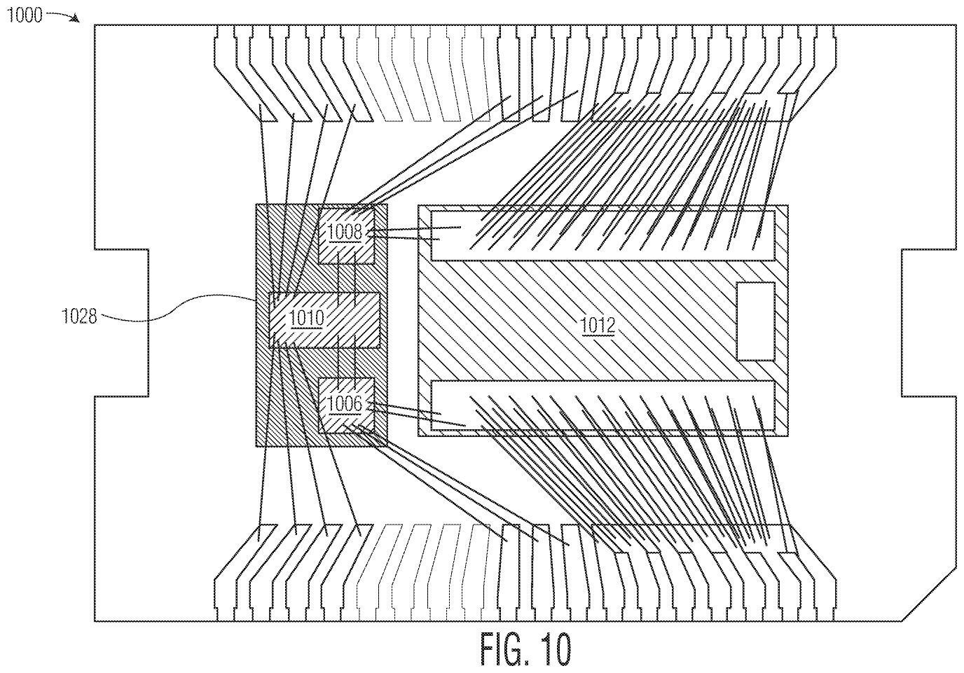

FIG. 10 illustrates a simplified partial plan view of an electronic package 1000 that includes a bidirectional switch, a first and second driver circuits, and an input/output circuit, according to an embodiment of the disclosure. As shown in FIG. 10, each of a bidirectional switch 1012, first and second driver circuits 1006 and 1008, respectively, and input/output circuit 1010 can be disposed on a separate die and can be arranged in a top-cooled power small-outline package (PSOP). The bidirectional switch 1012 can have a substrate connection that is coupled to a corresponding package pin. The first and second driver circuits 1006 and 1008, respectively, can be coupled to the bidirectional switch 1012 by wirebonds. The first and second driver circuits 1006 and 1008, respectively, can also be coupled to the input/output circuit 1010 by wirebonds. The first and second driver circuits 1006 and 1008, respectively, can also be coupled to their corresponding package pins by wirebonds. The input/output circuit 1010 circuit can be coupled to its corresponding package pins by wirebonds. The electronic package 1000 can also include a spacer 1028 that may be formed from, for example, Alumina (Al₂O₃) or aluminum nitride, or an insulating tape. The spacer 1028 can be electrically isolating. In some embodiments, the spacer may have low thermally conductive characteristics. Most of the heat dissipation can occur by the bidirectional switch through the top. The spacer can be disposed under the first and second driver circuits 1006 and 1008, respectively, and the input/output circuit 1010 dies, thereby isolating the first and second driver circuits 1006 and 1008, respectively, and the input/output circuit 1010 from the bidirectional switch 1012, as well as isolating the first driver circuit 1006 from the second driver circuit 1008. An electrically insulative encapsulant can be formed around the electronic package 1000.

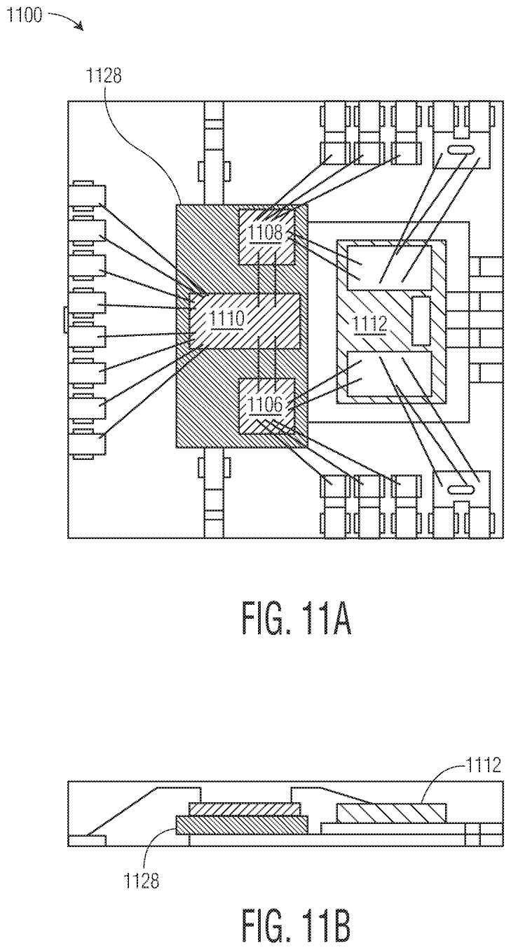

FIG. 11A illustrates a simplified partial plan view of an electronic package 1100 that includes a bidirectional switch, a first and second driver circuits, and an input/output circuit, according to an embodiment of the disclosure. FIG. 11B illustrates a simplified partial cross-sectional view of the electronic package 1100. As shown in FIGS. 11A and 11B, each of a bidirectional switch 1112, first and second driver circuits 1106 and 1108, respectively, and input/output circuit 1110 can be disposed on a separate die and can be arranged in a quad flat no-lead (QFN) package. In some embodiments, the electronic package 1100 can be an 8×8 QFN package. The bidirectional switch 1112 can have a substrate connection that is coupled to a corresponding package pin. The first and second driver circuits 1106 and 1108, respectively, can be coupled to the bidirectional switch 1112 by wirebonds. The first and second driver circuits 1106 and 1108, respectively, can also be coupled to the input/output circuit 1110 by wirebonds.

The first and second driver circuits 1106 and 1108, respectively, can also be coupled to their corresponding package pins by wirebonds. The input/output circuit 1110 circuit can be coupled to its corresponding package pins by wirebonds. The electronic package 1100 can also include a spacer 1128 that may be formed from, for example, Alumina (Al₂O₃) or aluminum nitride, or an insulating tape. The spacer 1028 can be electrically isolating. The spacer 1128 can be electrically isolating. In some embodiments, the spacer may have low thermally conductive characteristics. The spacer can be disposed under the first and second driver circuits 1106 and 1108, respectively, and the input/output circuit 1110 dies, thereby isolating the first and second driver circuits 1106 and 1108, respectively, and the input/output circuit 1110 from the bidirectional switch 1112, as well as isolating the first driver circuit 1106 from the second driver circuit 1108. In this way, the electronic package 1100 may be used, for example, in A/C circuit breakers. An electrically insulative encapsulant can be formed around the electronic package 1100.

FIG. 11A illustrates a 6×6 QFN. Other configurations of QFN packages are within the scope of this disclosure such as, but not limited to, 6×8 QFN having a similar configuration as the 6×6 QFN with relatively longer dimension in the horizontal dimension. In the 6×8 QFN, the right-hand part may be relatively longer, and the pins may be disposed to the right, and the bidirectional switch 1112 may be relatively longer showing a relatively larger die size for lower on-resistance.

In some embodiments, the isolation of the driver circuits and the bidirectional switch can be achieved by using floating pads of copper or floating copper inner-connects that are not connected to any external lead. This can be a pre-molded frame technology where the frame is half etched and then molded and then etched again to disconnect the leads.

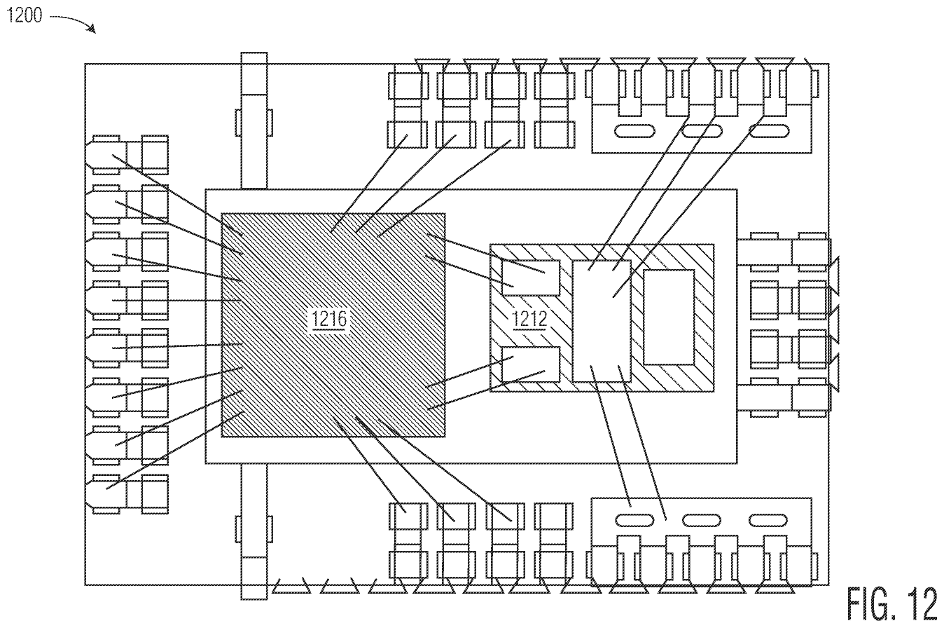

FIG. 12 illustrates a simplified partial plan view of an electronic package 1200 that includes a bidirectional switch, a first and second driver circuits, and an input/output circuit, according to an embodiment of the disclosure. The electronic package 1200 can be a QFN package. As shown in FIGS. 12, electronic package 1200 can include a bidirectional switch 1212 disposed on a first die, and a thin QFN (TQFN) package 1216 that may include first and second driver circuits, and an input/output circuit. The TQFN package 1216 can be configured to act as an isolator for the first and second driver circuits, and input/output circuit. In some embodiments, the TQFN 1216 may be attached to the electronic package 1200 upside down and use the terminal as bonding pad for final assembly of the electronic package 1200. An electrically insulative encapsulant can be formed around the electronic package 1200.

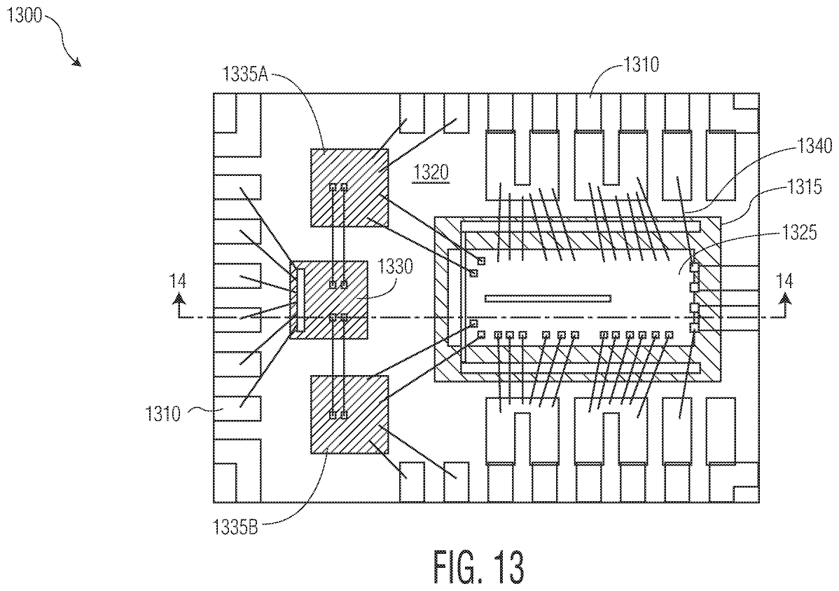

FIG. 13 illustrates a simplified partially transparent plan view of an electronic package 1300 in accordance with the disclosed embodiments. Electronic package 1300 may be or include any of the components, features, or characteristics of any of the electronic packages and/or components previously described, and the electronic package may be included in circuits as previously discussed. As shown in FIG. 13, electronic package 1300 includes a package base 1305 that has a plurality of external terminals 1310 and an electrically conductive die attach pad 1315 partially encapsulated in an electrically insulative polymer 1320. A bidirectional switch 1325 is attached to the die attach pad 1315 using solder, silver sintering material, an adhesive or other suitable material. A transmitter die 1330 and first and second receiver dies 1335A, 1335B, respectively, are attached to the electrically insulative polymer 1320 using an adhesive or other suitable material. One or more wirebonds 1340 are used to electrically connect the transmitter die 1330, the first and second receiver dies 1335A, 1335B, respectively, and the external terminals 1310. The physical arrangement and interconnections shown in FIG. 13 are for example only and other electronic packages may have other suitable arrangements and interconnections.

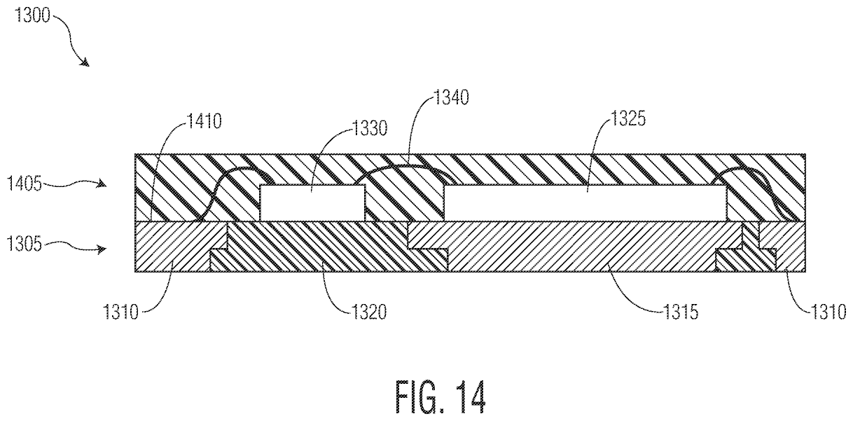

FIG. 14 illustrates a simplified cross-section of the electronic package 1300 illustrated in FIG. 13. As shown in FIG. 14, electronic package 1300 includes a package base 1305 that is partially encapsulated by a mold cap 1405 that extends across a top surface 1410 of the package base. Package base 1305 includes a die attach pad 1315 and a plurality of external terminals 1310 that may be made from an electrically conductive material such as copper or other suitable material. The electrically insulative polymer 1320 at least partially encapsulates the die attach pad 1315 and the plurality of external terminals 1310, providing electrical insulation between the electrically conductive regions. The bidirectional switch 1325 is thermally and/or electrically attached to the die attach pad 1315. Transmitter die 1330 is attached to a region of the electrically insulative polymer 1320 and is electrically isolated from the die attach pad 1315 and the plurality of external terminals 1310. One or more wirebonds 1340 electrically connect the transmitter die 1330 and the external terminals 1310. In other embodiments metallic clips, flip-chips or other suitable interconnects can be used. Mold cap 1405 is formed from an electrically insulative material and encapsulates the transmitter die 1330, the bidirectional switch 1325 as well as the one or more wirebonds 1340.

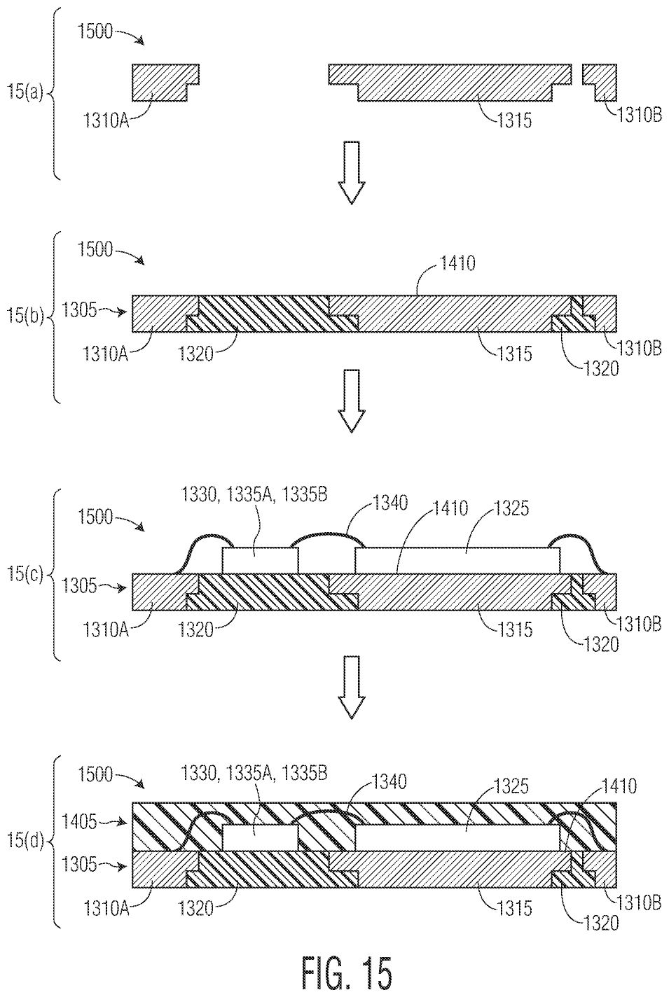

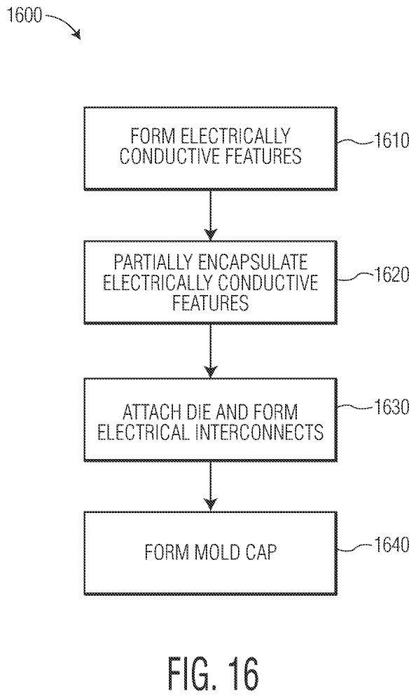

FIGS. 15A-15D illustrate steps associated with a method 1600 (see FIG. 16) of forming an electronic package 1500, according to embodiments of the disclosure. More specifically, FIGS. 15A-15D illustrate simplified cross-sectional views of the electronic package with each view corresponding to a particular step of method 1600. Electronic package 1500 may be similar to electronic package 1300 illustrated in FIGS. 13 and 14 with like reference numbers referring to similar features. Electronic package 1500 may be or include any of the components, features, or characteristics of any of the electronic packages and/or components previously described, and the electronic package may be included in circuits as previously discussed.

In a first step 1610, a plurality of electrically conductive features may be formed. As shown in section 15(a) of FIG. 15, the electrically conductive features in this particular embodiment include first and second external terminals 1310A, 1310B, respectively, and die attach pad 1315. In some embodiments the electrically conductive features may be formed using a build-up process employing various plating and lithography masks, while in other embodiments the electrically conductive features may be formed with a removal process including etching, machining or other material removal process. The electrically conductive features may be formed from any suitable metal or combination of metals including, but not limited to, copper, nickel, tin, aluminum, gold, palladium or iron.

In a second step 1620 the electrically conductive features may be partially encapsulated in an electrically insulative polymer 1320. As shown in section 15(b) of FIG. 15, the electrically insulative polymer 1320 fills in gaps between the electrically conductive features forming a relatively coplanar top surface 1410 of a base 1305 of the electronic package 1500. The electrically insulative polymer 1320 may be made from any suitable material that does not conduct electricity and may be formed using injection molding or other suitable process.

In a third step 1630 one or more dies are attached to the top surface 1410 of the base 1305 and one or more wirebonds 1340 are used to electrically connect the one or more die to one another and/or to the electrically conductive features. As shown in section 15(c) of FIG. 15, a bidirectional switch 1325 is attached to die attach pad 1315 and transmitter and/or receiver dies 1330, 1335A, 1335B are attached to electrically insulative polymer 1320. Wirebonds 1340 electrically connect the transmitter and/or receiver dies to each other and to one or more external terminals 1310. Wirebonds 1340 also electrically connect the transmitter and/or receiver dies to the bidirectional switch 1325 and further connect the bidirectional switch to the one or more external terminals 1310.

In a fourth step 1640 a mold cap 1405 is formed. As shown in section 15(d) of FIG. 15, the mold cap 1405 is formed across top surface 1410 of package base 1305 and encapsulates the transmitter and/or receiver dies 1330, 1335A, 1335B and the bidirectional switch 1325 as well as the one or more wirebonds 1340. Mold cap 1405 may be formed from any suitable electrically insulative material and may be formed via injection molding, transfer molding or other suitable process.

It will be appreciated that method 1600 is illustrative and that variations and modifications are possible. Steps described as sequential may be executed in parallel, order of steps may be varied, and steps may be modified, combined, added or omitted.

In some embodiments, combination of the circuits and methods disclosed herein can be utilized to form and operate integrated bidirectional switch with driver and input/output circuits. Although circuits and methods are described and illustrated herein with respect to several particular configuration of an integrated bidirectional switch with driver and input/output circuits, embodiments of the disclosure are suitable for forming other integrated bidirectional switches with driver and input/output circuits. Further, embodiments of the disclosure can be utilized in power converter circuits, such as but not limited to, AC-DC power converters, AC-AC power converters, and boost power converters.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom or “top” and the like can be used to describe an element and/or feature's relationship to other element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. An electronic system comprising:
an electronic package including a base having a plurality of external terminals, and further including an electrically insulative material at least partially encapsulating the base;
a controller circuit disposed within the electronic package and referenced to a first ground;
a first and second driver circuits disposed within the electronic package and referenced to a second ground, and arranged to receive isolated control signals from the controller circuit; and
a bidirectional switch disposed within the electronic package and referenced to the second ground and arranged to receive drive signals from the first and second driver circuits.

2. The electronic system of claim 1, wherein the first and second driver circuits are isolated from the controller circuit via capacitors, magnetics, optocouplers or magneto resistors.

3. The electronic system of claim 1, wherein the bidirectional switch is a first bidirectional switch and wherein the first bidirectional switch comprises a first gate terminal, a second gate terminal, a first source terminal and a second source terminal.

4. The electronic system of claim 3, wherein the first source terminal is coupled to a first external terminal of the plurality of external terminals and the second source terminal is coupled to a second external terminal of the plurality of external terminals.

5. The electronic system of claim 1, wherein the bidirectional switch is gallium nitride (GaN) based.

6. The electronic system of claim 3, wherein the first driver circuit is coupled to the first gate terminal, and the second driver circuit is coupled to the second gate terminal.

7. The electronic system of claim 1, wherein the first driver circuit is disposed on a first die, the second driver circuit is disposed on a second die, the controller circuit is disposed on a third die and the bidirectional switch is disposed on a fourth die.

8. The electronic system of claim 7, wherein the fourth die further comprises a sense device arranged to transmit a signal, to the controller circuit, including at least one of a magnitude and polarity of a current through the bidirectional switch.

9. The electronic system of claim 3, wherein the first driver circuit is arranged to transmit a first drive signal to the first gate terminal in response to receiving a first control signal from the control circuit and the second driver circuit is arranged to transmit a second drive signal to the second gate terminal in response to receiving a second control signal from the control circuit.

10. The electronic system of claim 3, further comprising a second bidirectional switch and a third bidirectional switch coupled in parallel to the first bidirectional switch.

11. The electronic system of claim 10, wherein an AC power supply referenced to the second ground is coupled between the first source terminal and the second source terminal, and wherein the second bidirectional switch and the third bidirectional switch are arranged to harvest energy from the AC power supply for operating the first and second driver circuits.

12. The electronic system of claim 11, wherein the second bidirectional switch comprises a depletion mode (D-mode) section and an enhancement mode (E-mode) section.

13. The electronic system of claim 11, wherein the second bidirectional switch is coupled in series with an energy harvesting capacitor.

14. The electronic system of claim 1, wherein the bidirectional switch is arranged to store energy harvested from a main input and use the harvested energy to provide power to the first and second driver circuits.

15. A method of forming an electronic component, the method comprising:
providing an electronic package including a base having a plurality of external forming an electrically insulative material at least partially encapsulating the base;
terminals;
disposing a controller circuit within the electronic package, the controller circuit referenced to a first ground;
disposing a first and second driver circuits within the electronic package, the first and second driver circuits referenced to a second ground, and arranged to receive isolated control signals from the controller circuit; and
disposing a bidirectional switch within the electronic package, the bidirectional switch referenced to the second ground and arranged to receive drive signals from the first and second driver circuits.

16. The method of claim 15, wherein the controller circuit is electrically isolated from the first and second driver circuits via capacitors, magnetics, optocouplers or magneto resistors.

17. The method of claim 15, wherein the first driver circuit is disposed on a first die, the second driver circuit is disposed on a second die, the controller circuit is disposed on a third die, and the bidirectional switch is disposed on a fourth die.

18. The method of claim 17, wherein the fourth die further comprises a sense device arranged to transmit a signal, to the control circuit, including at least one of a magnitude and polarity of a current through the bidirectional switch.

19. The method of claim 18, wherein the first driver circuit is arranged to transmit a first drive signal to a first gate terminal of the bidirectional switch in response to receiving a first control signal from the control circuit and the second driver circuit is arranged to transmit a second drive signal to a second gate terminal of the bidirectional switch in response to receiving a second control signal from the control circuit.

20. A method of operating a circuit, the method comprising:
providing an electronic package including a base having a plurality of external terminals, and further including an electrically insulative material at least partially encapsulating the base;
providing an input/output circuit disposed within the electronic package and referenced to a first ground;
providing a first and second driver circuits disposed within the electronic package and referenced to a second ground, and arranged to receive isolated control signals from the input/output circuit;
providing a bidirectional switch disposed within the electronic package and referenced to the second ground and arranged to receive drive signals from the first and second driver circuits;
receiving, by the input/output circuit, input data;
transmitting, by the input/output circuit, intermediate data corresponding to the input data;
receiving, by the first and second driver circuits, the intermediate data;
producing, by the first and second driver circuits, output data corresponding to the input data; and
driving, by the first and second driver circuits, the bidirectional switch with the output data.
